(19) United States
(12) Patent Application Publication
(10) Pub. No.: US 2026/0173445 A1
(43) Pub. Date: Jun. 18, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/981,003

(22) Filed: Dec. 13, 2024

(51) Int. Cl. H10D 30/67; H10D 30/00; H10D 30/01; H10D 30/43; H10D 30/69; H10D 62/10; H10D 62/83; H10D 84/01; H10D 84/83

(52) U.S. Cl. CPC H10D 30/6713; H10D 30/014; H10D 30/0191; H10D 30/43; H10D 30/502; H10D 30/6735; H10D 30/792; H10D 62/116; H10D 62/121; H10D 62/83; H10D 84/013; H10D 84/832

(57) ABSTRACT

Embodiments of the present disclosure provide semiconductor device structures and methods of forming the same. The structure includes one or more semiconductor layers disposed over a substrate portion, a source/drain region disposed adjacent the substrate portion and the one or more semiconductor layers, and a first stressor layer disposed below the source/drain region, wherein an air gap is formed between the first stressor layer and the source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6A, 6B, 6C, 6D are various cross-sectional side views of the semiconductor device structure of FIG. 5, in accordance with some embodiments.

FIGS. 7A, 7B, 7C, 7D are various cross-sectional side views of one of various stages of manufacturing the semiconductor device structure, in accordance with some embodiments.

FIGS. 8A, 9A, 10A, 11A, 12A, 13A, 14A, 15A, 16A, 17A, 18A, 19A. 21A, 21A, 22A, 23A, and 24A are cross-sectional side views of various stages of manufacturing the semiconductor device structure taken along line A-A of FIG. 5, in accordance with some embodiments.

FIGS. 8B, 9B, 10B, 11B, 12B, 13B, 13C, 14B, 15B, 16B, 17B, 18B, 19B, 20B, 21B, 22B, 23B, and 24B are cross-sectional side views of various stages of manufacturing the semiconductor device structure taken along line D-D of FIG. 5, in accordance with some embodiments.

FIGS. 25A, 26A, 27A, 28A, 29A, 30A, 31A, 32A, 33A, 34A, 35A, 36A. 37A, 38A, 39A, 40A, and 41A are cross-sectional side views of various stages of manufacturing the semiconductor device structure taken along line A-A of FIG. 5, in accordance with alternative embodiments.

FIGS. 25B, 26B, 27B, 28B, 29B, 30B, 31B, 32B, 33B, 34B, 35B, 36B, 37B, 38B, 39B, 40B, and 41B are cross-sectional side views of various stages of manufacturing the semiconductor device structure taken along line D-D of FIG. 5, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures having an air gap between a dielectric layer and a bottom of a source/drain region to increase carrier mobility of the source/drain region. In some embodiments, a dielectric layer is formed on the top surface of the source/drain region to further increase carrier mobility of the source/drain region.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

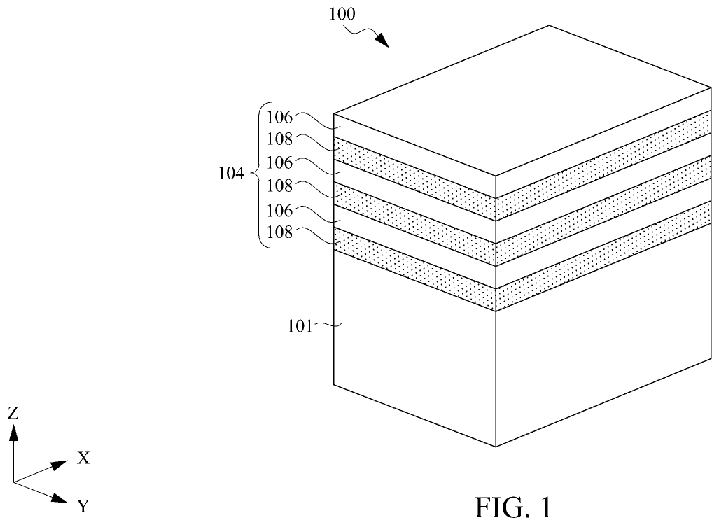

FIGS. 1-24B show exemplary processes for manufacturing a semiconductor device structure 100 according to embodiments of the present disclosure. It is understood that additional operations can be provided before, during, and after processes shown by FIGS. 1-24B, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

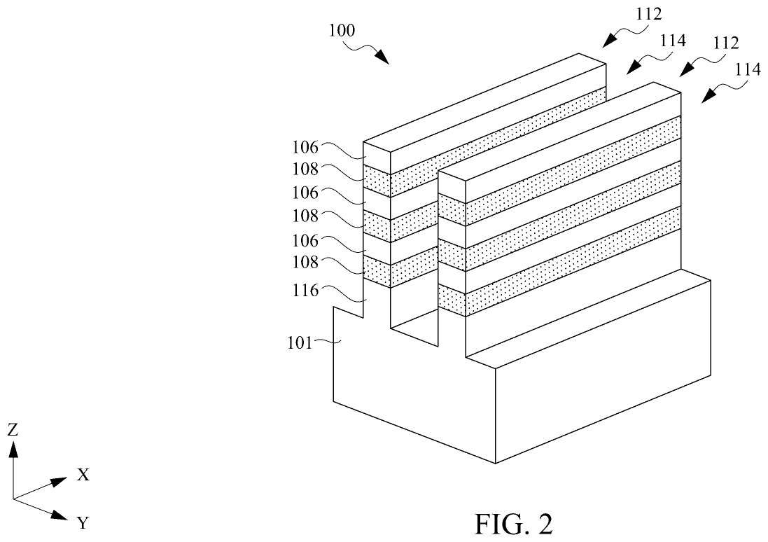

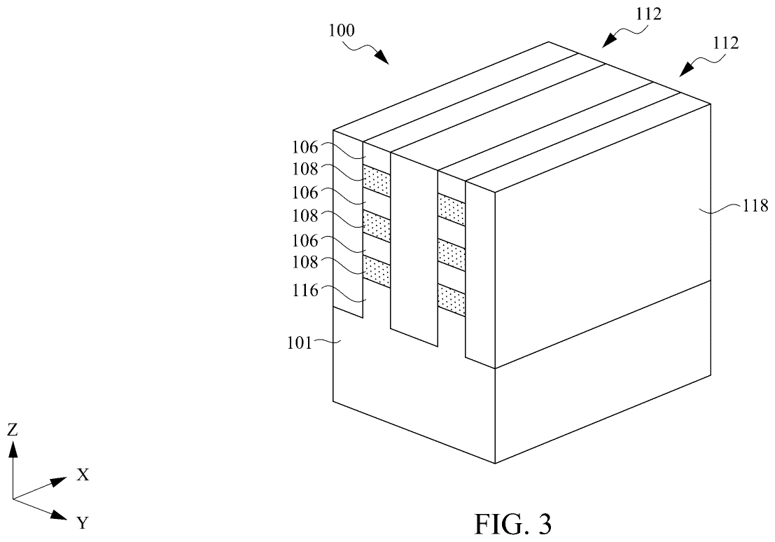

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

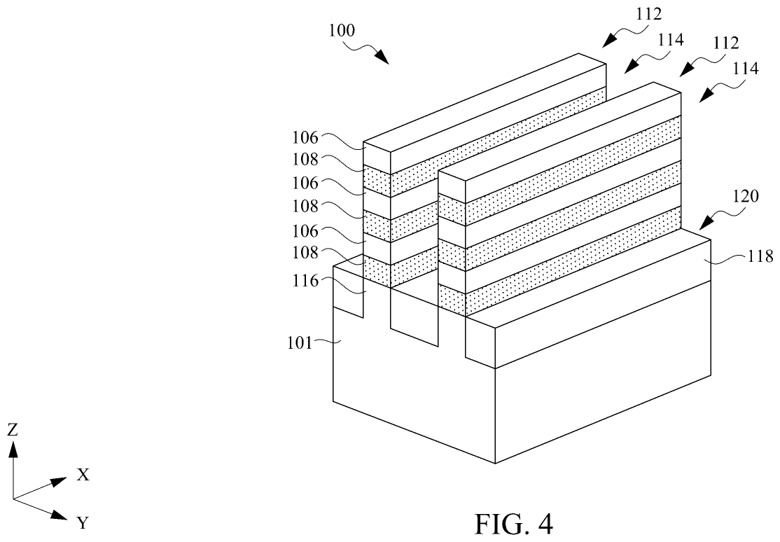

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

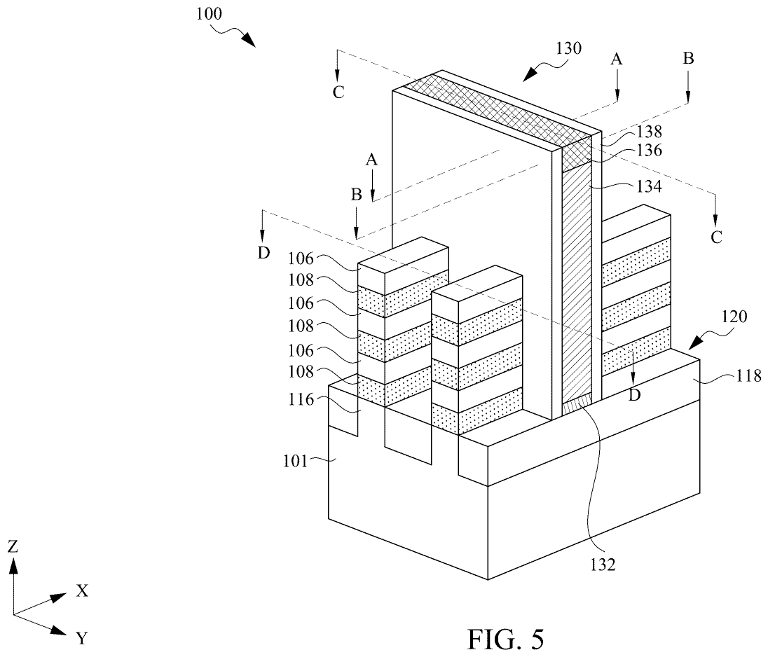

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

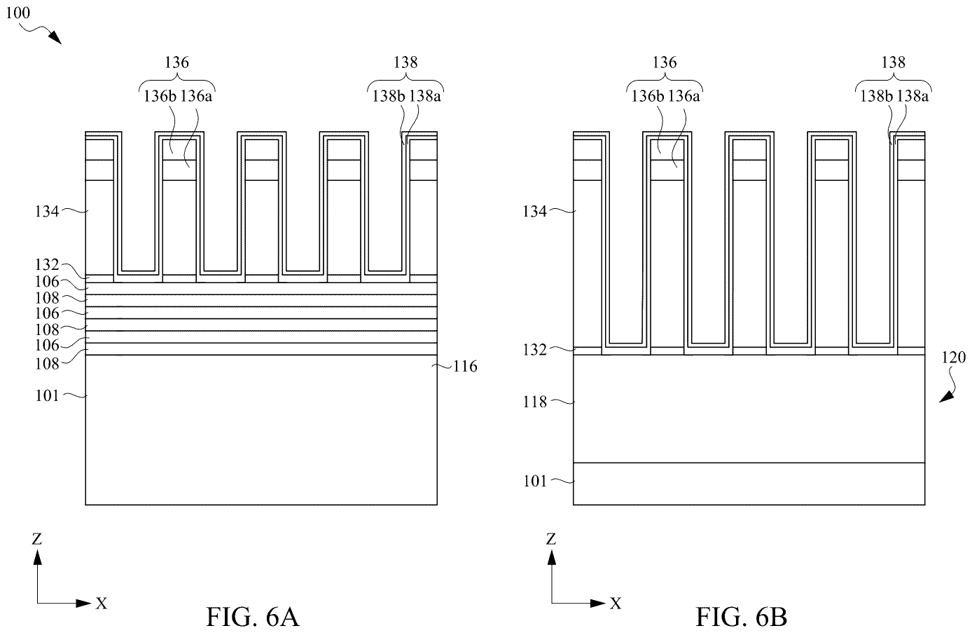

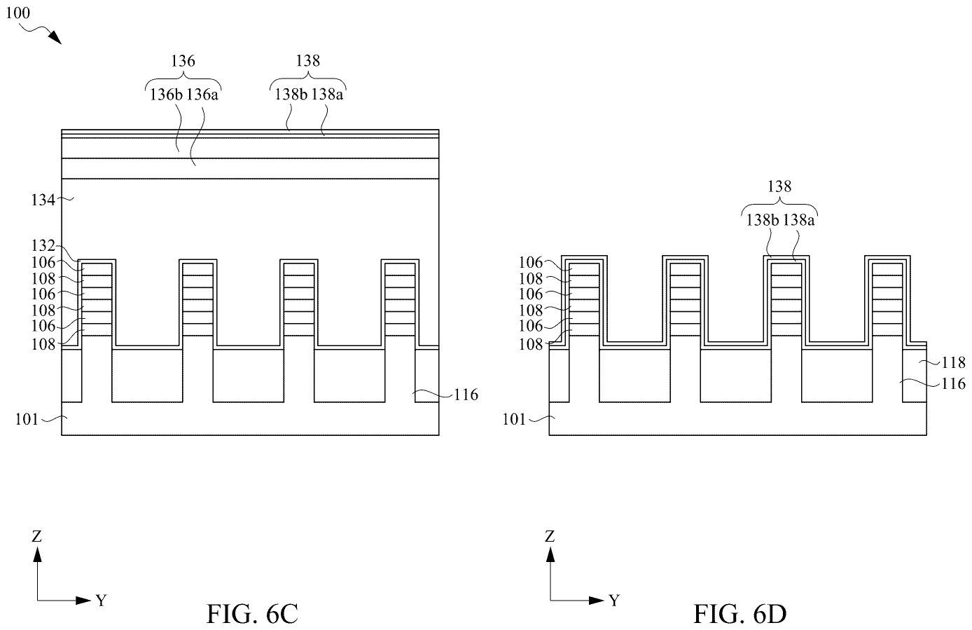

FIGS. 6A, 6B, 6C, 6D are various cross-sectional side views of the semiconductor device structure 100 taken along line A-A, line B-B, line C-C, and line D-D of FIG. 5, respectively, in accordance with some embodiments. As shown in FIGS. 6A, 6B, 6C, and 6D, in some embodiments, the mask layer 136 includes an oxide layer 136a and a nitride layer 136b, and the gate spacers 138 includes a first gate spacer 138a and a second gate spacer 138b. Furthermore, in some embodiments, the gate spacer 138 is formed around the exposed portions of the fin structures 112, as shown in FIG. 6D.

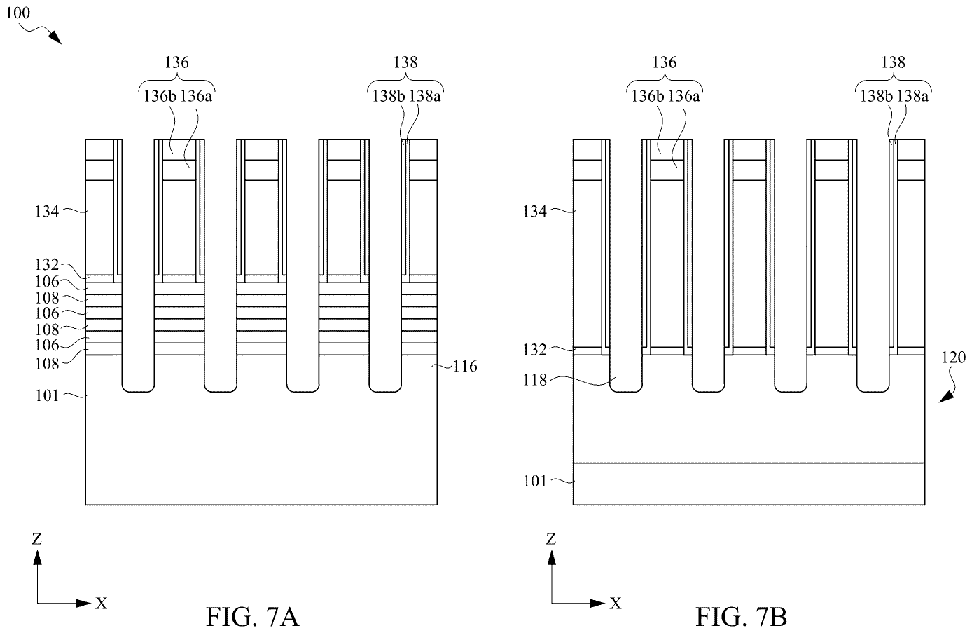

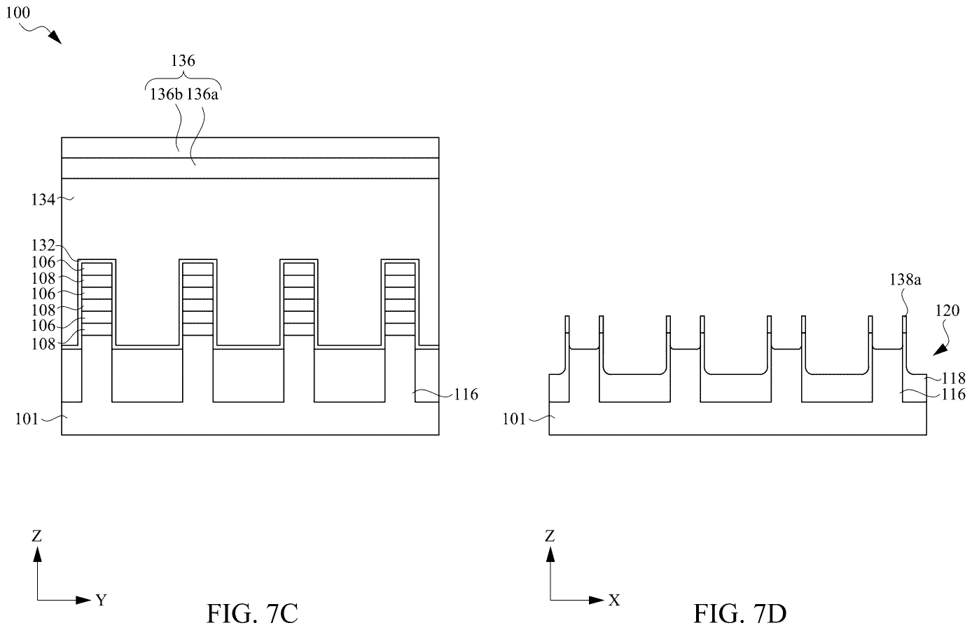

FIGS. 7A, 7B, 7C, 7D are various cross-sectional side views of the semiconductor device structure 100 taken along line A-A, line B-B, line C-C, and line D-D of FIG. 5, respectively, in accordance with some embodiments. As shown in FIGS. 7A-7D, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. In some embodiments, as shown in FIGS. 7B and 7D, a portion of the insulating material 118 of the isolation region 120 is also removed during the recess of the exposed portions of the fin structures 112. In some embodiments, the horizontal portions of the gate spacers 138a, 138b are removed, as shown in FIGS. 7A, 7B, 7C, and 7D. In some embodiments, the portion of the second gate spacer 138b formed around the exposed portions of the fin structures 112 is removed, and the portion of the first gate spacer 138a formed around the exposed portions of the fin structures 112 is recessed, as shown in FIG. 7D.

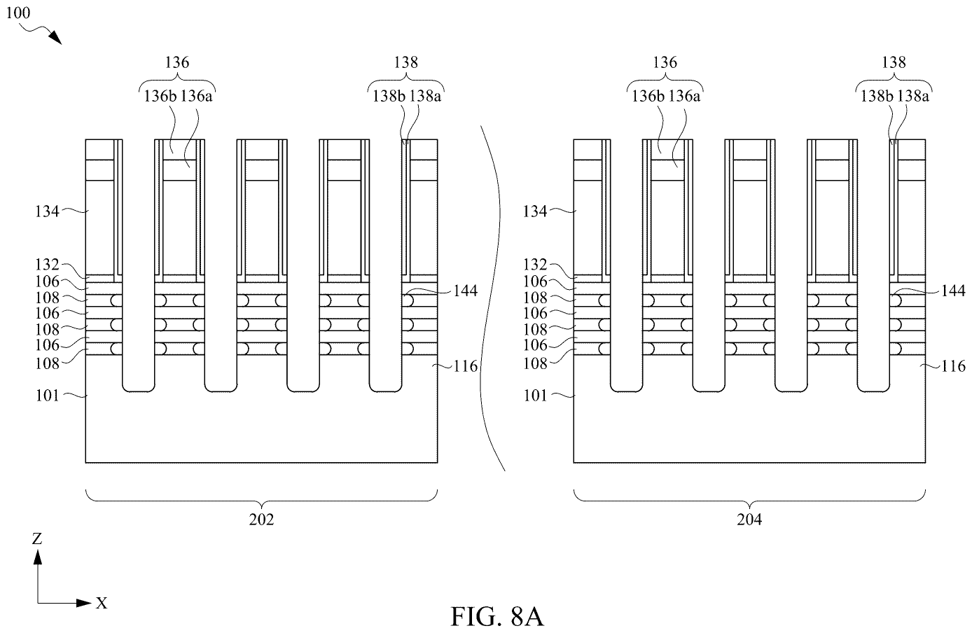

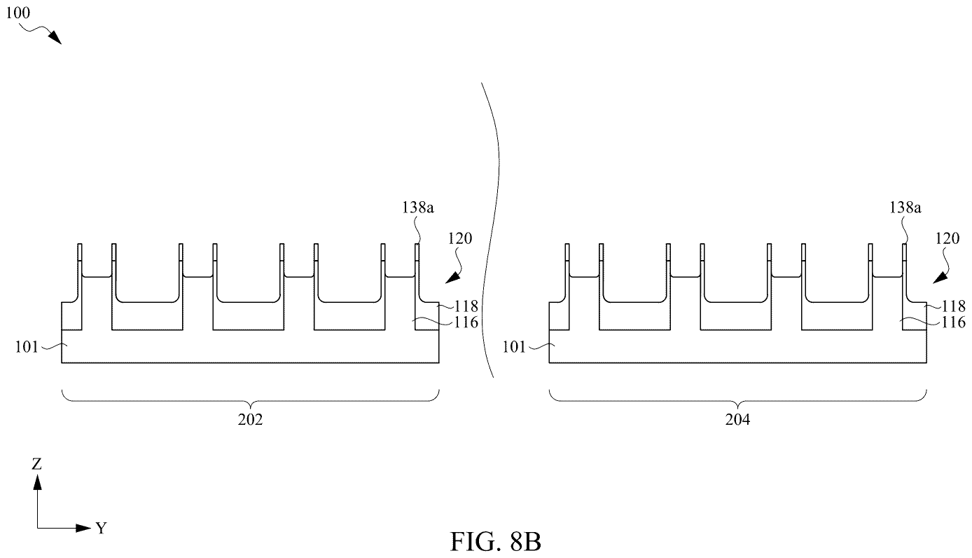

FIGS. 8A, 9A, 10A, 11A, 12A, 13A, 14A, 15A, 16A, 17A, 18A, 19A. 21A, 21A, 22A, 23A, and 24A are cross-sectional side views of various stages of manufacturing the semiconductor device structure 100 taken along line A-A of FIG. 5, in accordance with some embodiments. FIGS. 8B, 9B, 10B, 11B, 12B, 13B, 13C, 14B, 15B, 16B, 17B, 18B, 19B, 20B, 21B, 22B, 23B, and 24B are cross-sectional side views of various stages of manufacturing the semiconductor device structure 100 taken along line D-D of FIG. 5, in accordance with some embodiments. In some embodiments, as shown in FIGS. 8A and 8B, the semiconductor device structure 100 includes a first region 202 and a second region 204. In some embodiments, the first region 202 is a p-type metal-oxide-semiconductor (PMOS) region, and the second region 204 is an n-type metal-oxide-semiconductor (NMOS) region. In some embodiments, the first region 202 is an NMOS region, and the second region 204 is a PMOS region. While not shown in scale in some figures, the first and second regions 202, 204 belong to a continuous substrate 101. In some embodiments, a first type devices, such as n-type devices or p-type devices, may be formed in the first region 202, while a second type of devices, such as p-type devices or n-type devices, may be formed in the second region 204. The first and second types are opposite types. N-type devices may be n-type FETs, and P-type devices may be p-type FETs.

As shown in FIG. 8A, edge portions of each second semiconductor layer 108 of the stack of semiconductor layers 104 in both first and second regions 202, 204 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layer 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

In some embodiments, instead of removing the edge portions of each second semiconductor layer 108, the second semiconductor layers 108 are removed and replaced with a dielectric material, such as high-density SiN or SiO. The edge portions of the dielectric material are removed, and the dielectric spacers 144 are formed to cap the dielectric material.

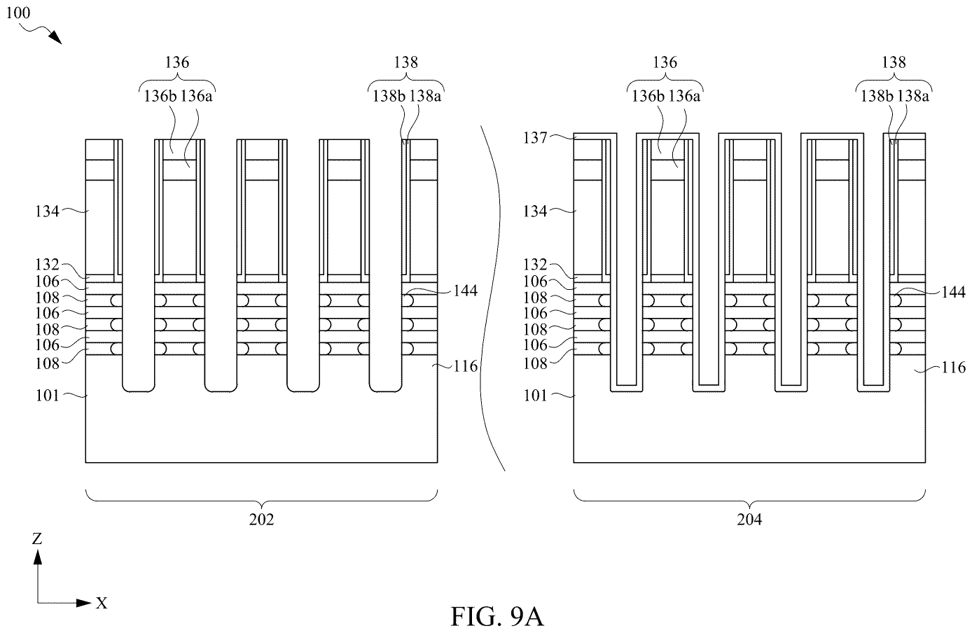

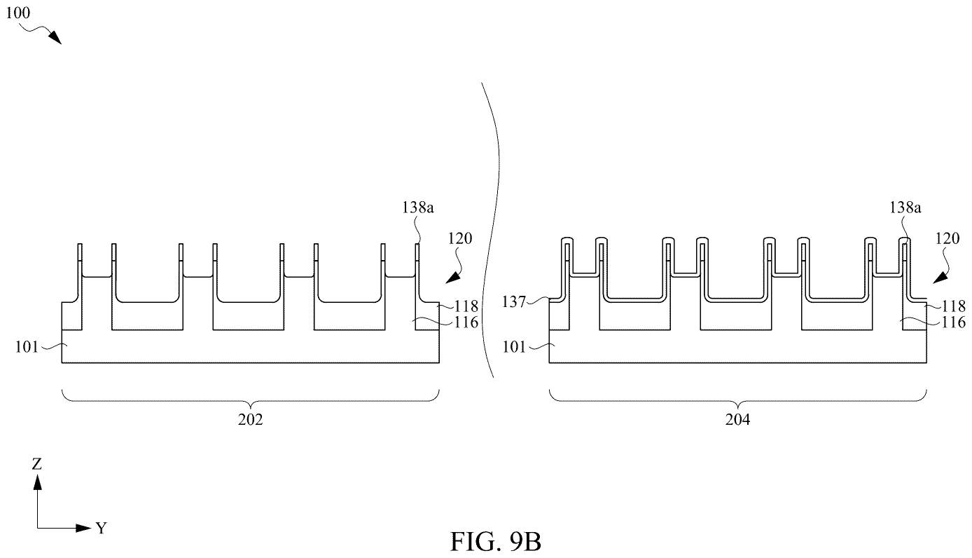

As shown in FIGS. 9A and 9B, a dielectric layer 137 is formed in the second region 204. The dielectric layer 137 covers the materials, especially the semiconductor materials, to prevent semiconductor materials grown epitaxially from the semiconductor materials in the second region 204. The dielectric layer 137 may include any suitable material. In some embodiments, the dielectric layer 137 is an oxide, such as a metal oxide. In some embodiments, the dielectric layer 137 is a nitride, such as silicon nitride. As shown in FIGS. 9A and 9B, the dielectric layer 137 may be a conformal layer formed by a conformal process, such as an ALD process. In some embodiments, the dielectric layer 137 is first formed on the surfaces of both first and second regions 202, 204, and a mask layer (not shown) is formed on the portion of the dielectric layer 137 in the second region 204. The exposed portion of the dielectric layer 137 in the first region 202 is removed. The mask layer may be any suitable mask layer, such as a photoresist layer or a bottom antireflective coating (BARC) layer. The mask layer is then removed in the second region 204 to expose the dielectric layer 137.

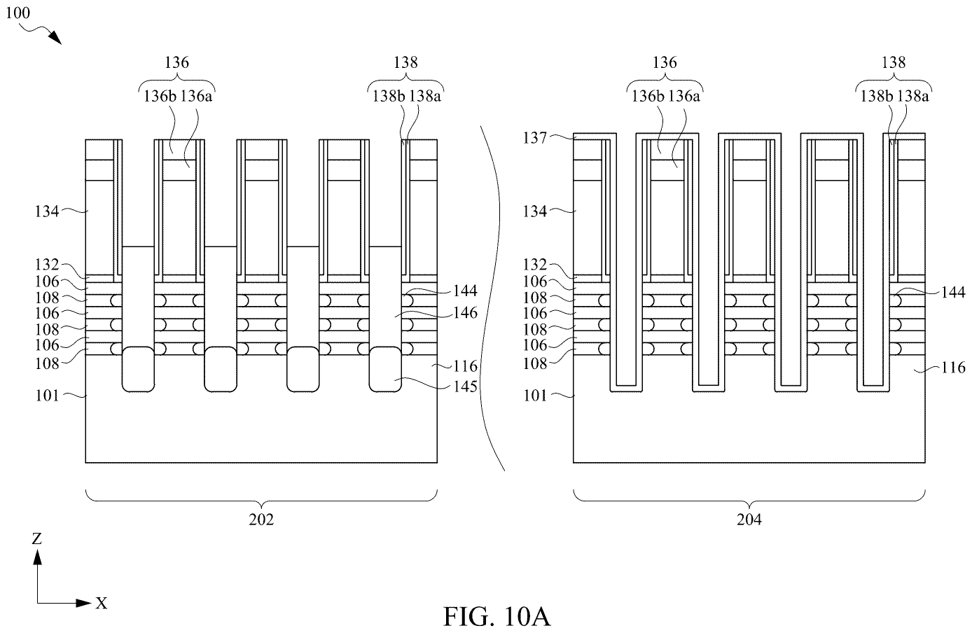

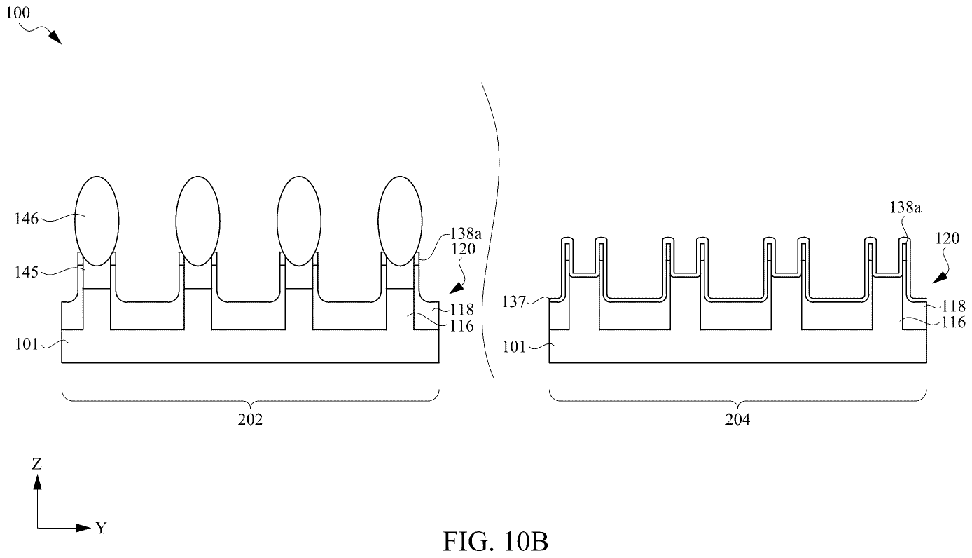

As shown in FIGS. 10A and 10B, a semiconductor material 145 and source/drain (S/D) regions 146 are formed in the first region 202. In some embodiments, the semiconductor material 145 includes undoped silicon and is formed by epitaxy. In some embodiments, the S/D regions 146 may grow both vertically and horizontally to form facets, which may correspond to crystalline planes of the materials used for the semiconductor material 145 and the first semiconductor layers 106. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, the first region 202 is an NMOS region, and the S/D regions 146 is made of one or more layers of Si, SiP, SiC and SiCP. In some embodiments, the first region 202 is a PMOS region, and the S/D regions 146 is made of one or more layers of Si, SiGe, and Ge. In some embodiments, the S/D region 146 is for an n-channel FET, and the S/D region 146 includes carbon, which can provide tensile stress on the S/D region. In some embodiments, the S/D region 146 is for a p-channel FET, and the S/D region 146 includes germanium, which can provide compressive stress. The compressive or tensile stress is a form of a longitudinal stress, which can boost the mobility of charge carrier when applied to the S/D region 146.

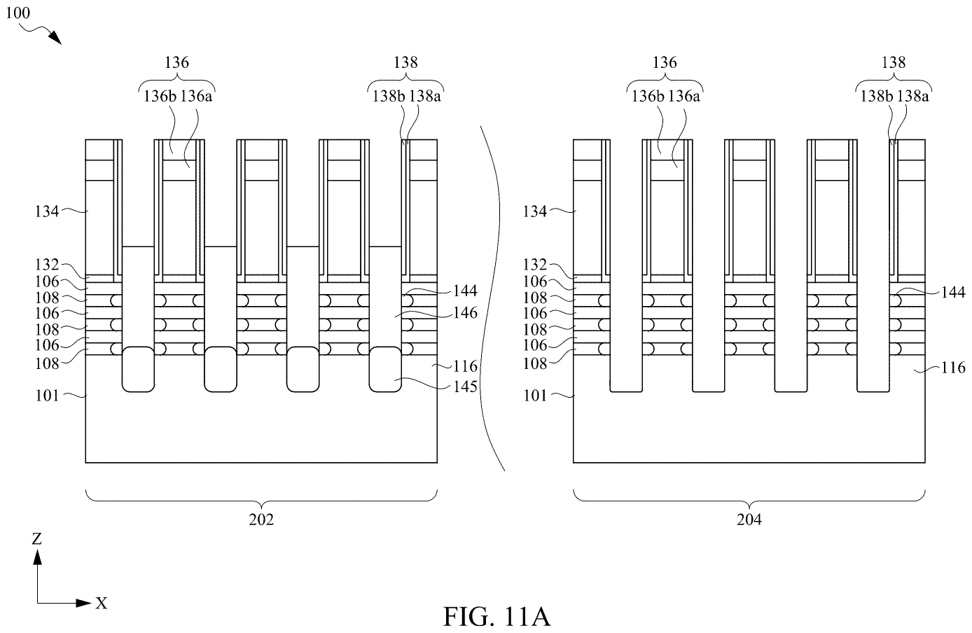

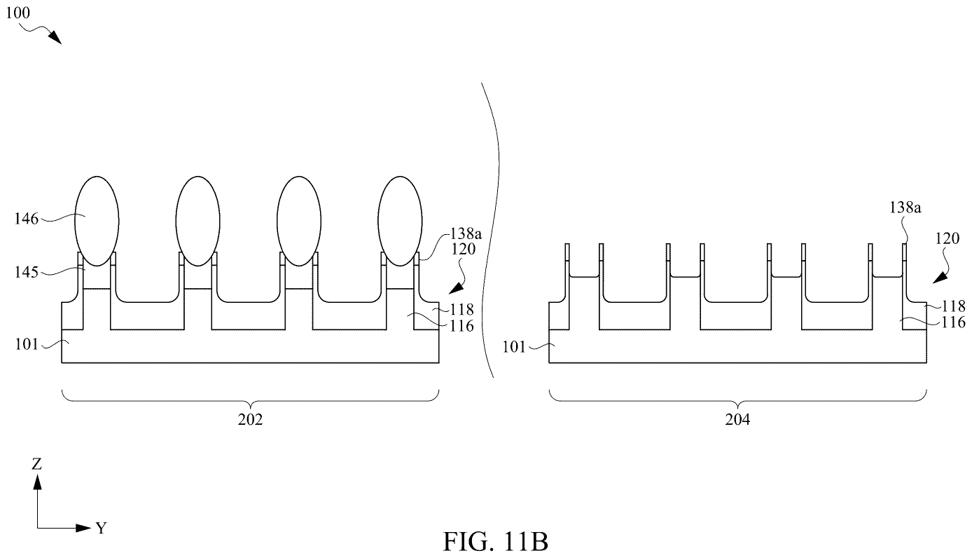

As shown in FIGS. 11A and 11B, the dielectric layer 137 in the second region 204 is removed. The dielectric layer 137 may be removed by any suitable process, such as a dry etch process, a wet etch process, or a combination thereof. In some embodiments, the dielectric layer 137 is removed by a selective etch process that does not substantially affect other materials of the semiconductor device structure 100.

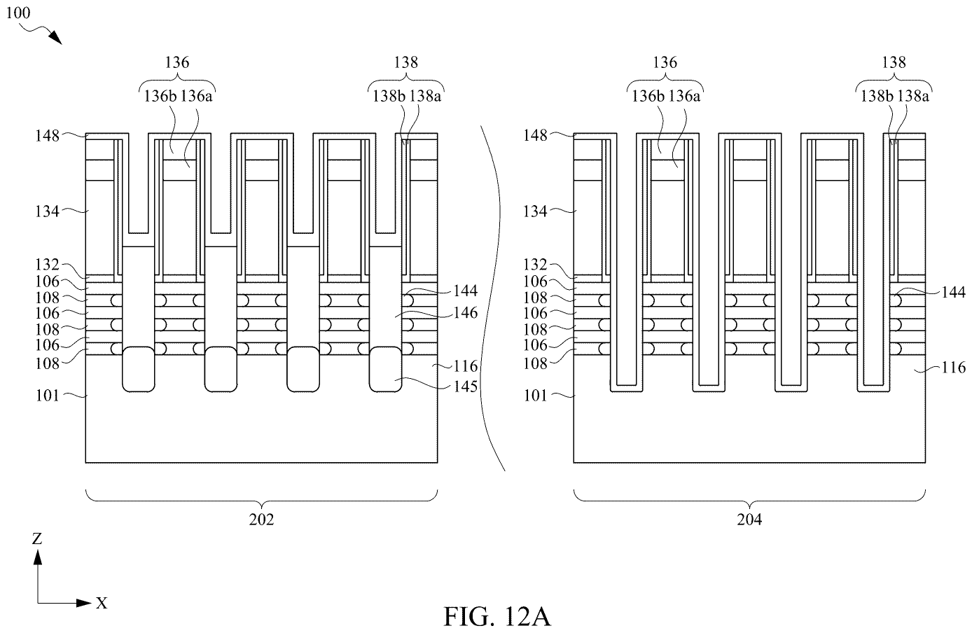

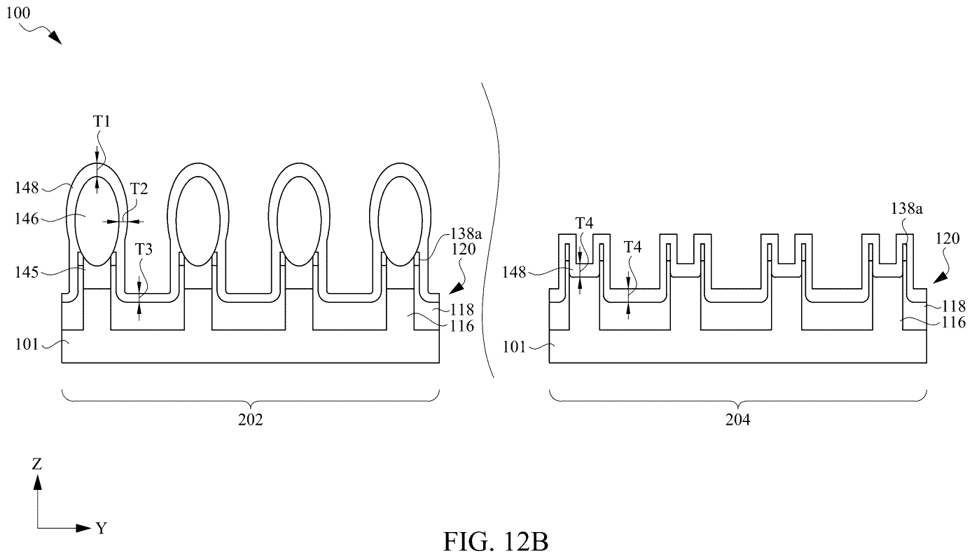

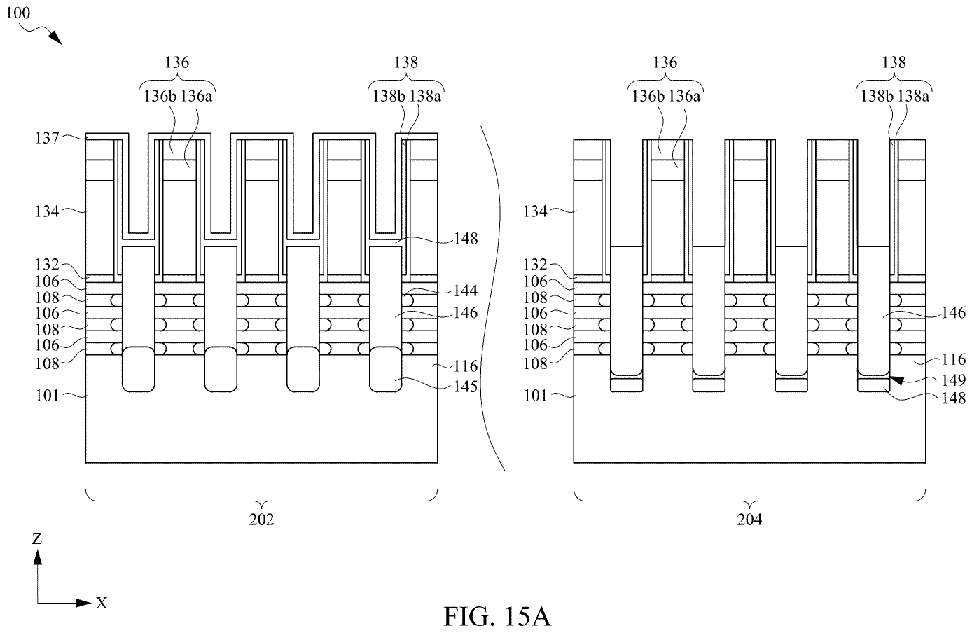

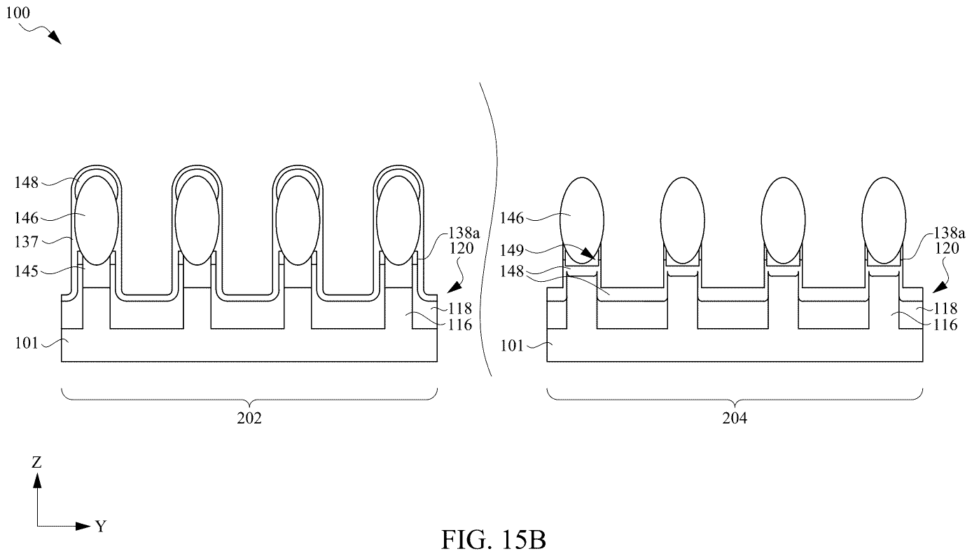

As shown in FIGS. 12A and 12B, a stressor layer 148 is deposited on the surfaces in the first and second regions 202, 204. The stressor layer 148 is deposited around the S/D regions 146 in the first region 202 and on the substrate portions 116 in the second region 204, as shown in FIG. 12B. The stressor layer 148 may include a material that can impact the longitudinal stress of the S/D region 146. For example, by forming the stressor layer 148 on top of the S/D region 146, the stressor layer 148 can provide traverse stress to impact the longitudinal stress. The traverse stress can impact the longitudinal stress based on the material's Young's modulus and Poisson ratio. In some embodiments, the stressor layer 148 includes Si₃N₄, which has a Young's modulus higher than that of the semiconductor material of the S/D region 146 and a Poisson ratio ranging from about 0.23 to about 0.28. In some embodiments, the stressor layer 148 includes multiple layers. For example, the stressor layer 148 may include a Si₃N₄ layer and a SiO₂ layer disposed on the Si₃N₄ layer. Even though the Young's modulus and the Poisson ratio of the SiO₂ layer are less than those of the Si₃N₄ layer, the SiO₂ layer may enable a formation of an air gap 149 (FIGS. 15A and 15B) in the second region 204, which will be discussed in detail below.

In some embodiments, the first region 202 is an NMOS region, and the stressor layer 148 can apply a tensile stress on the S/D region 146 to boost charge carrier mobility. In some embodiments, the first region 204 is a PMOS region, and the stressor layer 148 can apply a compressive stress on the S/D region 146 to boost charge carrier mobility. In some embodiments, the stressor layer 148 includes a Si₃N₄ layer that can apply compressive stress or a Si₃N₄ layer that can apply tensile stress.

In some embodiments, the thickness of the stressor layer 148 varies. For example, the portion of the stressor layer 148 formed on the top surface of the S/D regions 146 has a thickness T1, the portion of the stressor layer 148 formed on the sidewall of the S/D regions 146 has a thickness T2, the portion of the stressor layer 148 formed on the insulating material 118 in the first region 202 has a thickness T3, and the portion of the stressor layer 148 formed on the substrate portion 116 and the portion of the stressor layer 148 formed on the insulating material 118 in the second region 204 have a thickness T4. In some embodiments, the thickness T1 is greater than the thickness T2 and the thickness T3, and the thickness T1 is about the same as the thickness T4. In some embodiments, the stressor layer 148 is deposited by chemical vapor deposition, and the portions of the stressor layer 148 formed on the horizontal surfaces have thicknesses greater than the thicknesses of the portions of the stressor layer 148 formed on the vertical surfaces. Furthermore, the insulating material 118 in the first region 202 is located at a bottom of an opening defined by the S/D regions 146, and the insulating material and the substrate portion 116 located in the second region 204 are more exposed than the insulating material 118 in the first region 204. Thus, in some embodiments, as shown in FIG. 12B, the thickness T3 of the portion of the stressor layer 148 is less than the thickness T4 of the portion of the stressor layer 148 formed on the substrate portion 116 and the insulating material 118 in the second region 204. In some embodiments, the portions of the stressor layer 148 formed on the mask layer 136 in the first and second regions 202, 204 have the thickness T1 or T4.

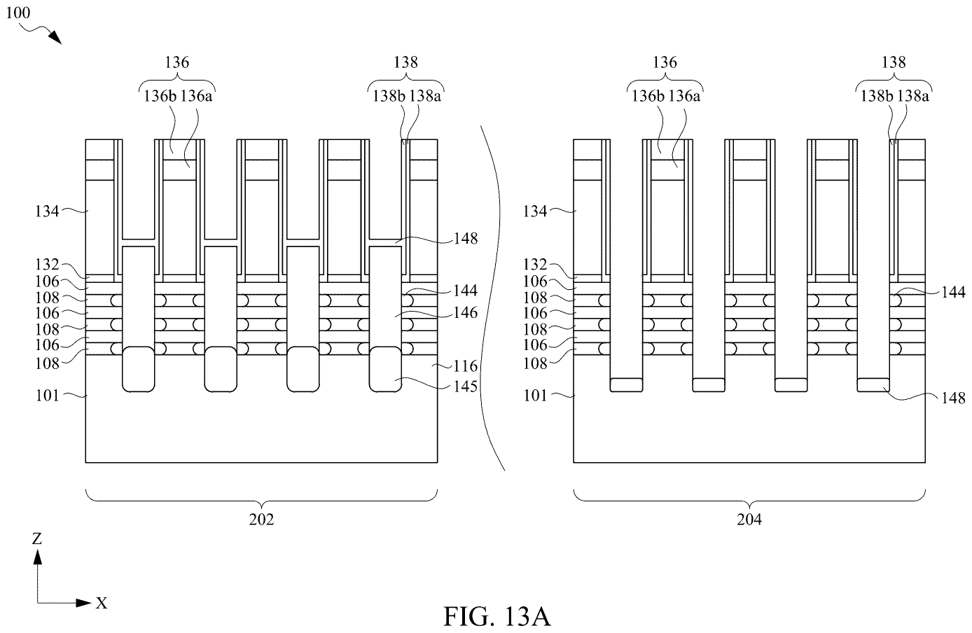

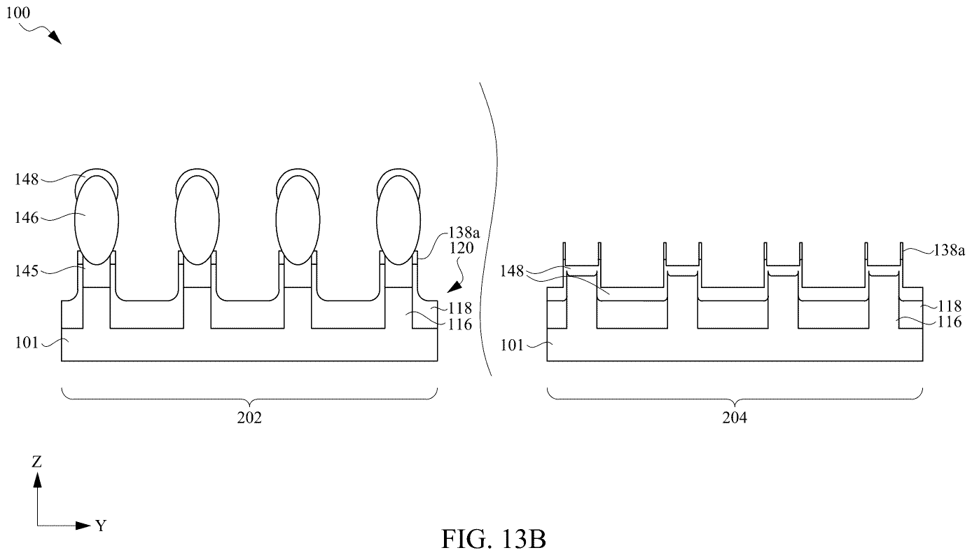

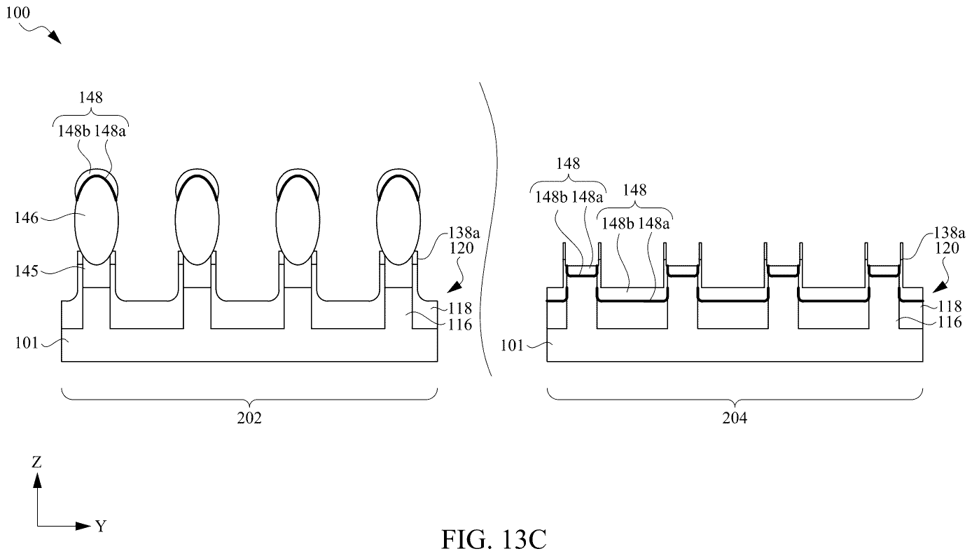

As shown in FIGS. 13A and 13B, a trimming process is performed on the stressor layer 148. In some embodiments, the stressor layer 148 is removed other than the portion of the stressor layer 148 formed on the S/D regions 146 in the first region 202 and the portion of the stressor layer 148 formed on the insulating material 118 and the substrate portion 116 in the second region 204. As described above, the stressor layer 148 has varying thicknesses. Thus, the trimming process, which may be a dry etch process or a wet etch process, removes the portions of the stressor layer 148 having a small thickness, while the portions of the stressor layer 148 having a large thickness remain on the semiconductor device structure 100, as shown in FIGS. 13A and 13B. For example, the thicknesses T1 and T4 of the portions of the stressor layer 148 are greater than the thicknesses T2 and T3 of the portions of the stressor layer 148. Thus, the portions of the stressor layer 148 having the thicknesses T2 and T3 are removed by the trimming process, while the portions of the stressor layer 148 having the thicknesses T1 and T4 are recessed. In some embodiments, although not shown, portions of the stressor layer 148 formed on the mask layer 136 may also remain.

FIG. 13C illustrating an alternate embodiment that the stressor layer 148 includes a first layer 148a and a second layer 148b. In some embodiments, the first layer 148a is made of Si₃N₄ and the second layer 148b is made of SiO₂. The first layer 148a, which is made of Si₃N₄, is in contact with the S/D regions 146 in the first region 202 to boost charge carrier mobility of the S/D regions 146. The second layer 148b, which is made of SiO₂, is formed over the substrate portions 116 in the second region 204 to enable the formation of an air gap 149 (FIGS. 15A and 15B) during the subsequent processes.

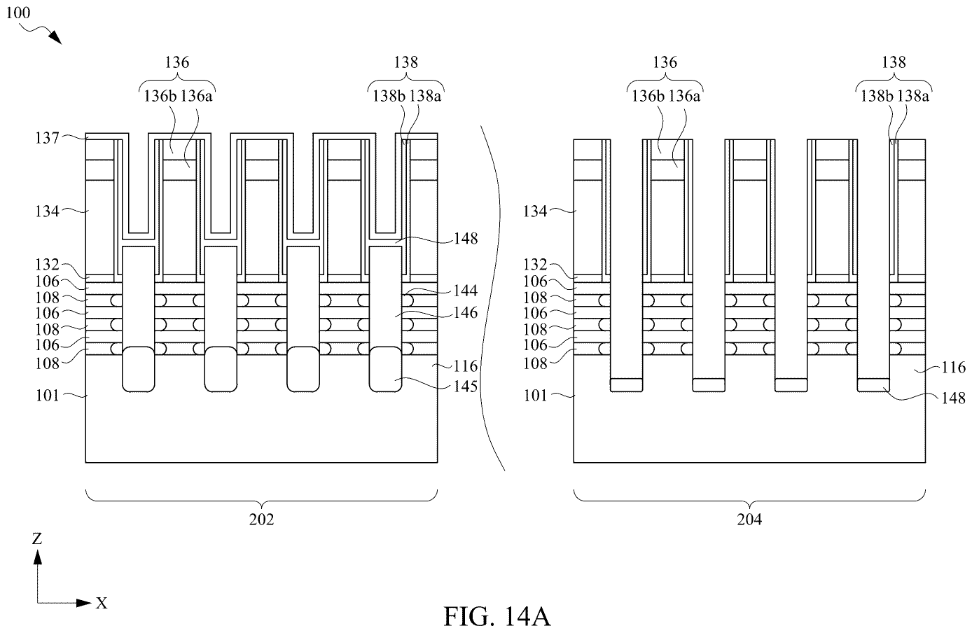

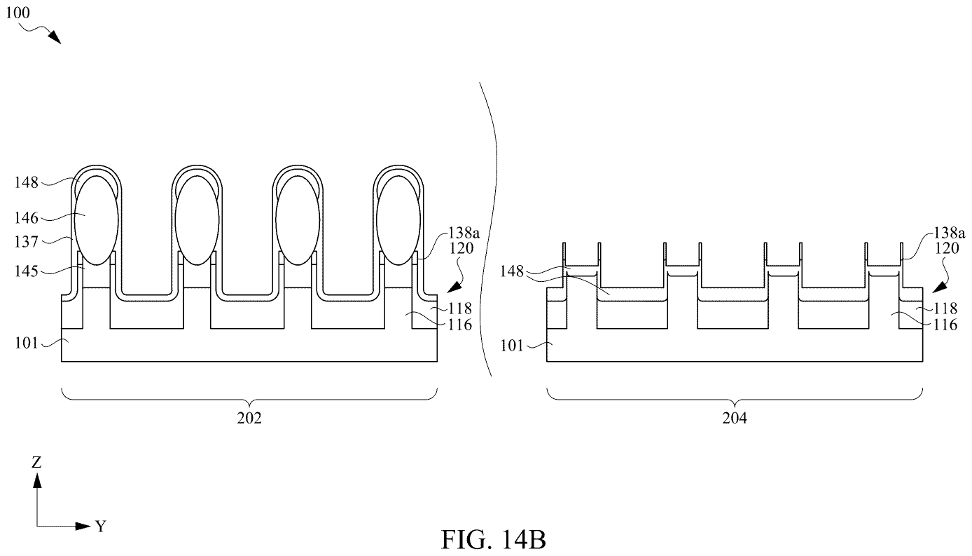

As shown in FIGS. 14A and 14B, another dielectric layer 137 is formed in the first region 202. Similarly to the processes described in FIGS. 9A and 9B, the dielectric layer 137 may be initially formed in both first and second regions 202, 204, and a mask layer (not shown) is formed in the first region 202. The exposed portions of the dielectric layer 137 in the second region 204 are removed, followed by the removal of the mask layer.

As shown in FIGS. 15A and 15B, S/D regions 146 are formed in the second region 204, and air gaps 149 are formed between the S/D regions 146 and the stressor layer 148 in the second region 204. As described above, the S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, the second region 204 is an NMOS region, and the S/D regions 146 is made of one or more layers of Si, SiP, SiC and SiCP. In some embodiments, the second region 204 is a PMOS region, and the S/D regions 146 is made of one or more layers of Si, SiGe, and Ge. In some embodiments, the S/D region 146 is for an n-channel FET, and the S/D region 146 includes carbon, which can provide tensile stress on the S/D region. In some embodiments, the S/D region 146 is for a p-channel FET, and the S/D region 146 includes germanium, which can provide compressive stress. The compressive or tensile stress is a form of a longitudinal stress, which can boost the mobility of charge carrier when applied to the S/D region 146.

In some embodiments, to ensure the air gaps 149 are formed between the S/D regions 146 and the stressor layer 148 in the second region 204, the stressor layer 148 includes the first layer 148a and the second layer 148b (FIG. 13C). As described above, in some embodiments, the second layer 148b includes SiO₂. In some embodiments, the second region 204 is an NMOS region, and a carbon-containing precursor, such as CH₄, may be used during the formation of the S/D regions 146. The carbon-containing precursor reacts with the SiO₂ of the second layer 148b to form gases, such as CO₂ and SiH₄. As a result, top portions of the second layer 148b are removed to form air gaps 149 in the second region 204, as shown in FIGS. 15A and 15B. In some embodiments, the second region 204 is a PMOS region, and a germanium-containing precursor, such as GeH₄, may be used during the formation of the S/D regions 146. The germanium-containing precursor reacts with the SiO₂ of the second layer 148b to form GeO₂, which is soluble in water. Thus, in some embodiments, after the formation of the S/D regions 146 in the second region 204, the top portion of the second layer 148b is converted to a layer of GeO₂. Next, a wet removal process that uses water, such as DI water, is performed to remove the layer of GeO₂. As a result, the air gaps 149 are formed between the S/D regions 146 and the stressor layer 148 in the second region 204, as shown in FIGS. 15A and 15B. In order to form the CO₂ and SiH₄ gases (if the second region 204 is an NMOS region) or to form the layer of GeO₂ (if the second region 204 is a PMOS region), the carbon-containing precursor (for NMOS region) or the germanium-containing precursor (for PMOS region) may be flowed into a processing chamber in which the semiconductor device structure 100 is placed therein with different flow rates. For example, the flow rate of the carbon-containing precursor or the germanium-containing precursor may be the highest at the beginning of the epitaxial process to form the S/D regions 146 in the second region 204, so the carbon-containing precursor or the germanium-containing precursor can react with the second layer 148b. As a result, the bottom of the S/D region 146 may include a higher concentration of carbon or germanium compared to other regions of the S/D region 146.

The stressor layer 148 formed in the second region 204 not only blocks the S/D regions 146 from growing from the substrate portions 116 but also ensures that the air gaps 149 are formed between the S/D regions 146 and the stressor layer 148. As describe above, carbon-containing or germanium-containing precursors are included during the formation of the S/D regions 146 in the second region 204 to provide a tensile or compressive stress on the S/D regions 146. By creating the air gaps 149, the lateral growth of the S/D regions 146 in the second region 204 along the X direction dominates the process. Thus, minimum stress loss of the S/D regions 146 can be realized by inhibiting vertical growth of the S/D regions 146.

The longitudinal stress of the S/D regions 146 in the first region 202 may be increased by including a carbon-containing precursor (for NMOS region) or a germanium-containing precursor (for PMOS region) during the formation of the S/D regions 146 and by forming the stressor layer 148 on the top surface of the S/D regions 146 in the first region 202. The stressor layer 148 (or the first layer 148a) may be amorphous and may be formed by ALD or CVD, which has small requirement on lattice matching. The longitudinal stress of the S/D regions 146 in the second region 204 may be increased by including a carbon-containing precursor (for NMOS region) or a germanium-containing precursor (for PMOS region) during the formation of the S/D regions 146 and by forming the air gaps 149 between the S/D regions 146 and the stressor layer 148.

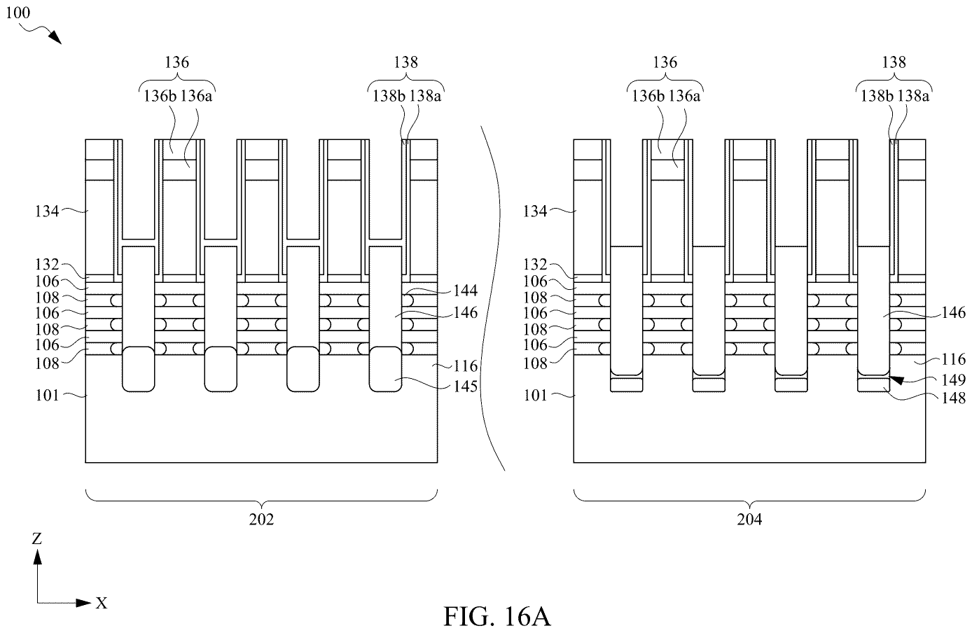

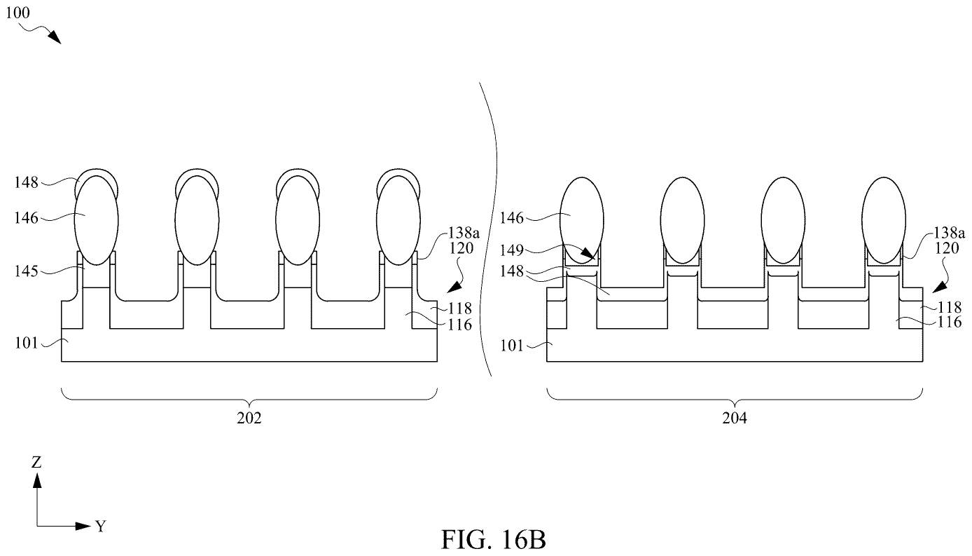

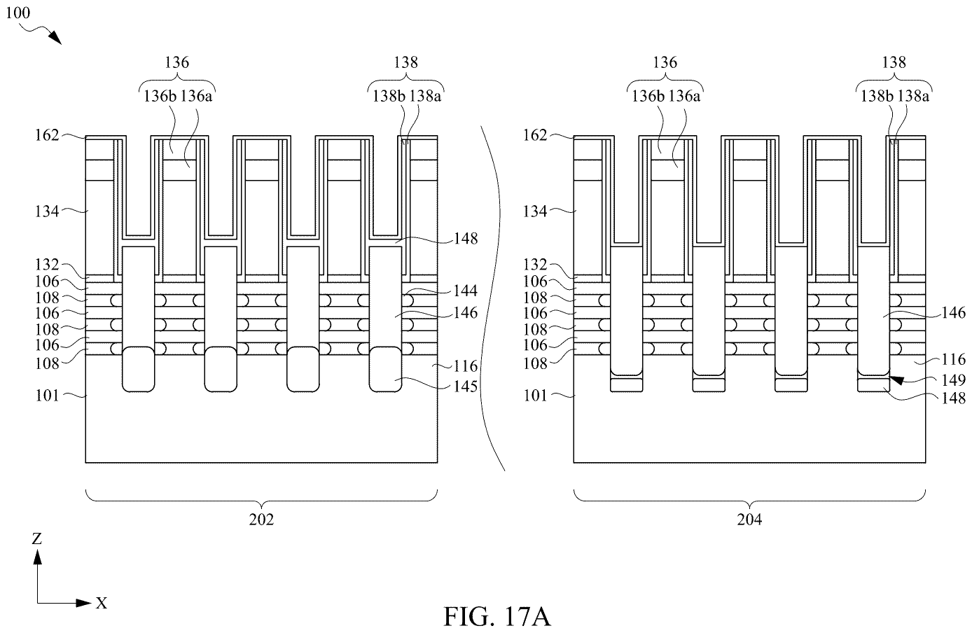

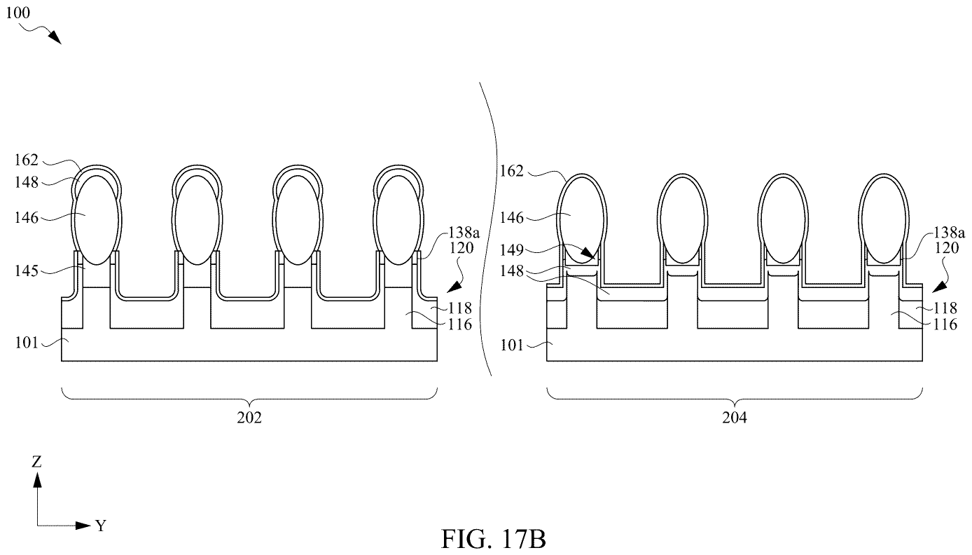

As shown in FIGS. 16A and 16B, the dielectric layer 137 is removed from the first region 202. The dielectric layer 137 may be removed by the same process described in FIGS. 11A and 11B. Next, as shown in FIGS. 17A and 17B, a contact etch stop layer (CESL) 162 is conformally formed on the exposed surfaces of the semiconductor device structure 100 in both first and second regions 202, 204. The CESL 162 covers the sidewalls of the gate spacers 138, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique.

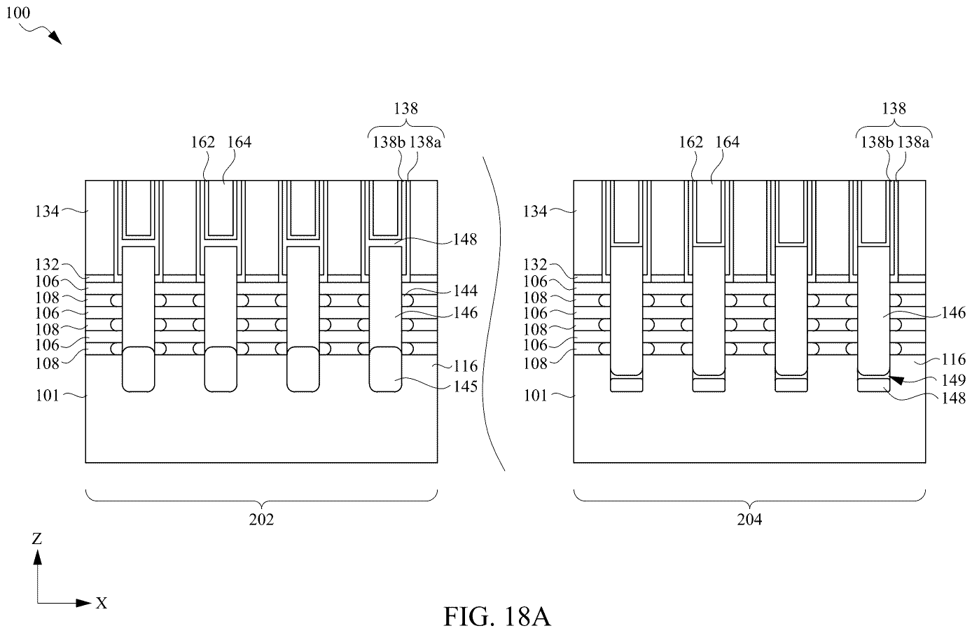

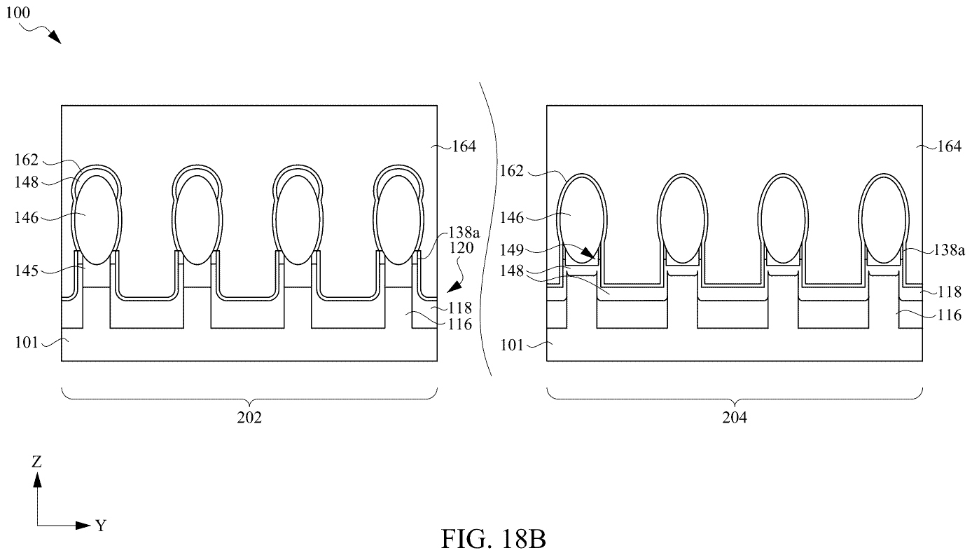

Next, as shown in FIGS. 18A and 18B, an interlayer dielectric (ILD) layer 164 is formed on the CESL 162 over the semiconductor device structure 100 in both first and second regions 202, 204. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

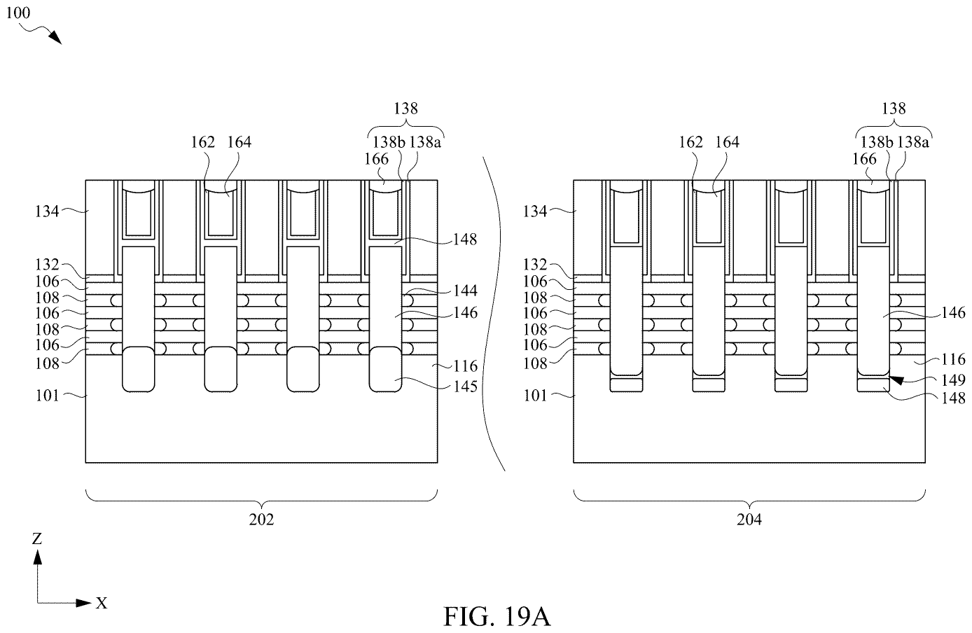

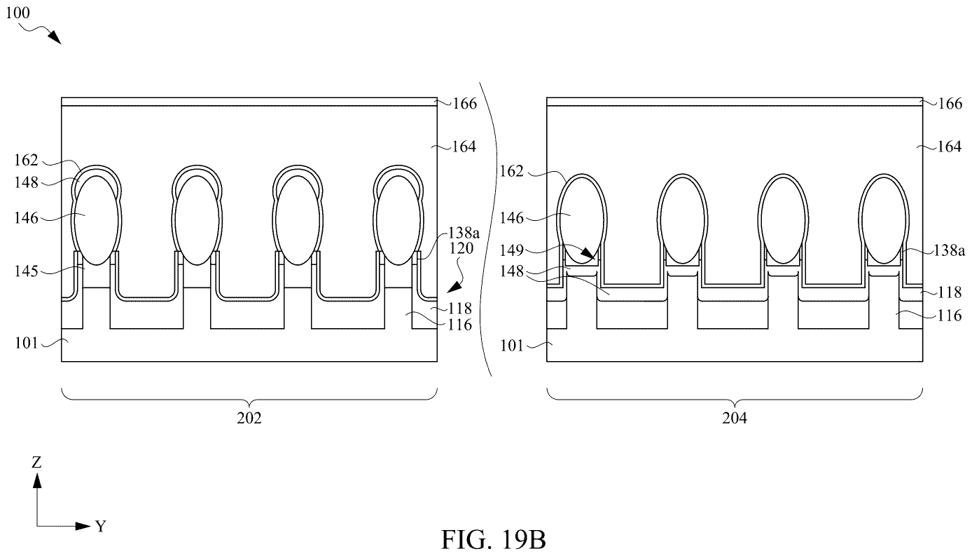

After the ILD layer 164 is formed, a planarization operation, such as CMP, is performed on the semiconductor device structure 100 until the sacrificial gate electrode layer 134 is exposed, as shown in FIGS. 18A and 18B. In some embodiments, after the planarization process, the ILD layer 164 is recessed, and a dielectric layer 166 is formed on the recessed ILD layer 164, as shown in FIGS. 19A and 19B. The dielectric layer 166 may include a nitride, such as silicon nitride, to protect the ILD layer 164 during subsequent processes. A second planarization process may be performed to remove portions of the dielectric layer 166 formed on the sacrificial gate electrode layer 134.

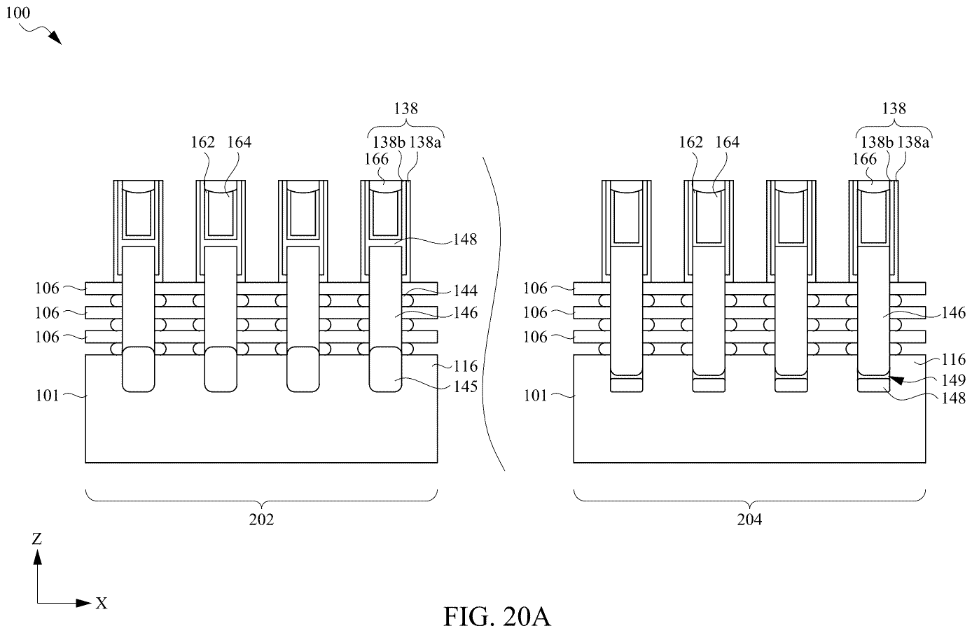

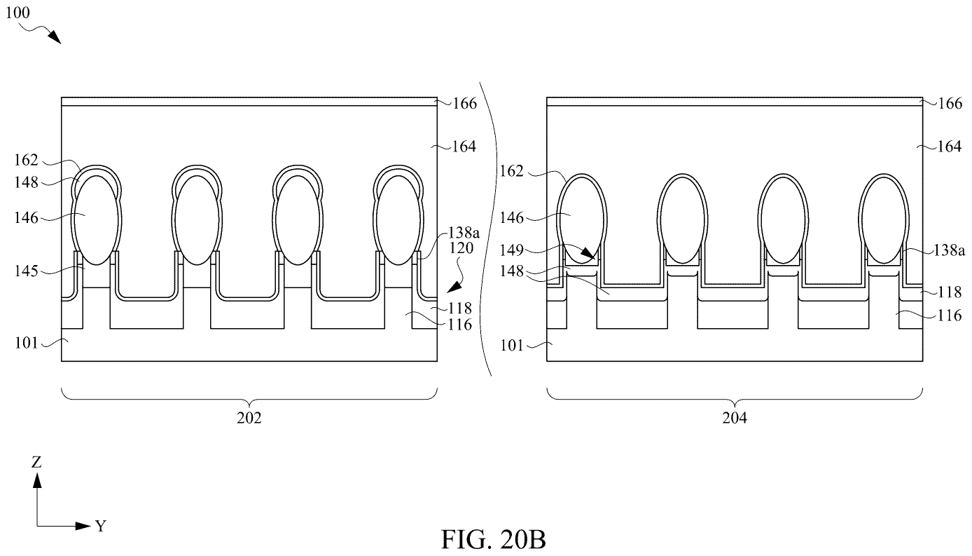

As shown in FIGS. 20A and 20B, the sacrificial gate structures 130 and the second semiconductor layers 108 are replaced with the gate dielectric layers 170 and the gate electrode layers 172. The removal of the sacrificial gate structure 130 and the semiconductor layers 108 forms an opening between gate spacers 138 and between first semiconductor layers 106. The dielectric material of the dielectric layers 166 is not substantially affected by the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138 and the dielectric layer 166.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, the dielectric layers 166, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

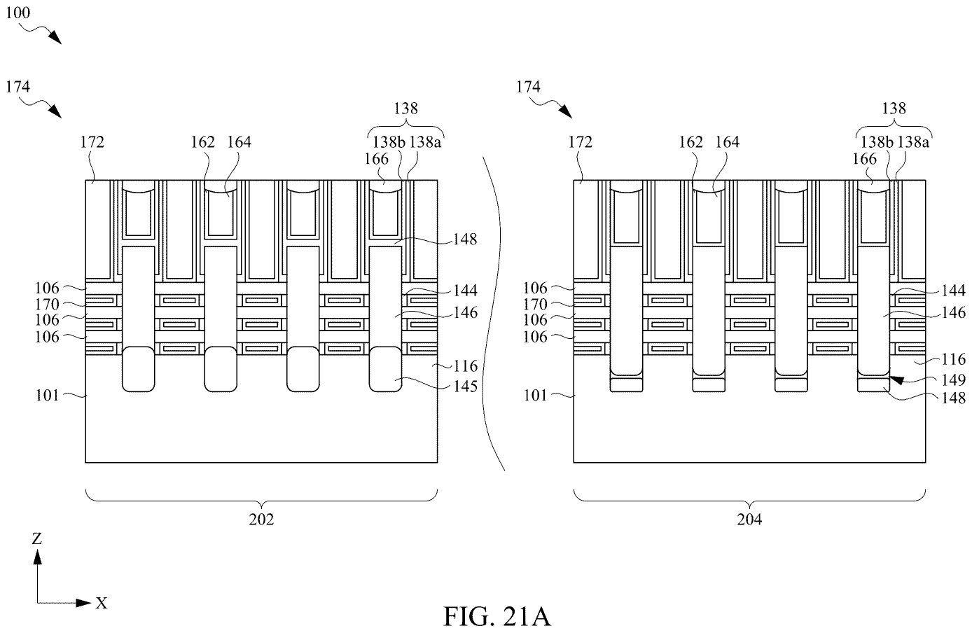

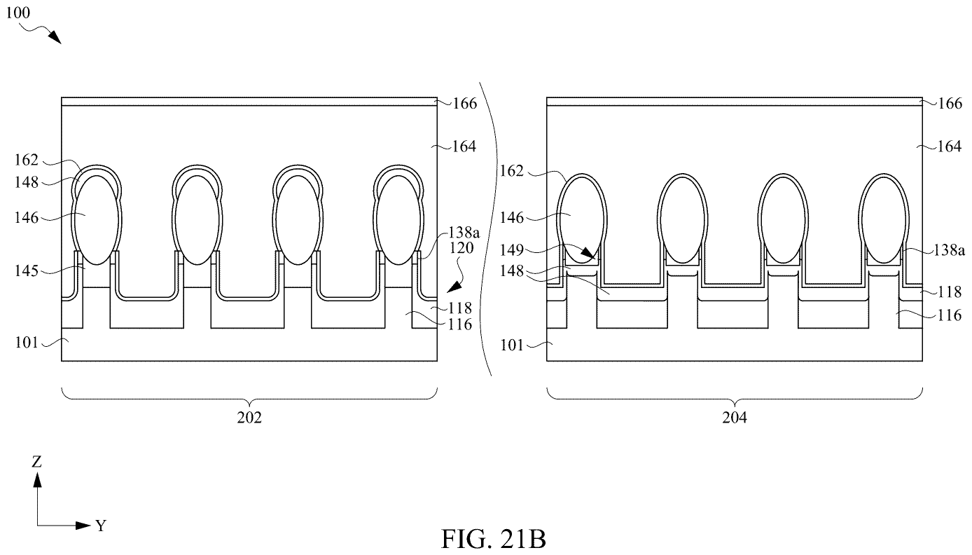

After the formation of the nanostructure channels (i.e., the exposed portions of the first semiconductor layers 106), the gate dielectric layer 170 is formed to surround the exposed portions of the first semiconductor layers 106, and the gate electrode layer 172 is formed on the gate dielectric layer 170, as shown in FIGS. 21A and 21B. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the dielectric layers 166. The gate dielectric layer 170 and the gate electrode layer 172 formed over the dielectric layers 166 are then removed by using, for example, CMP, until the top surfaces of the dielectric layers 166 are exposed.

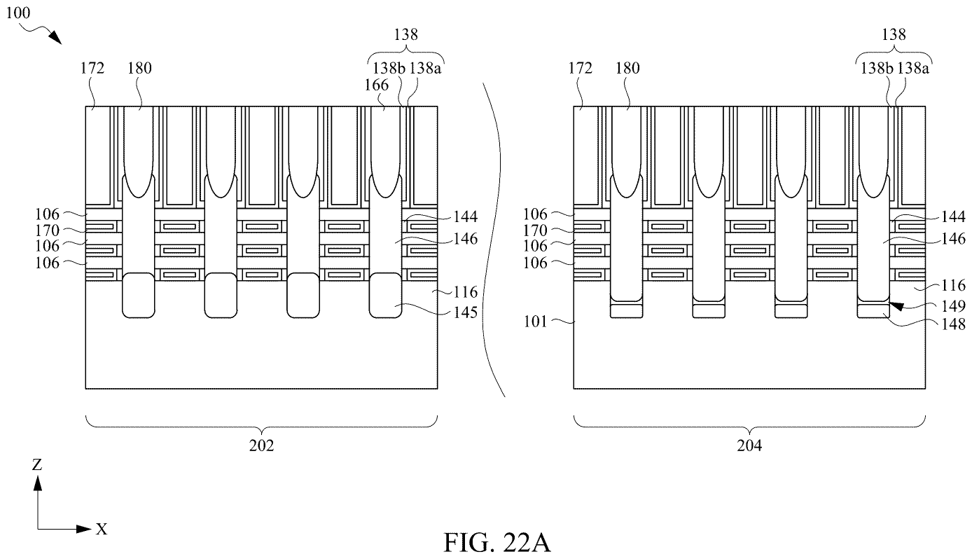

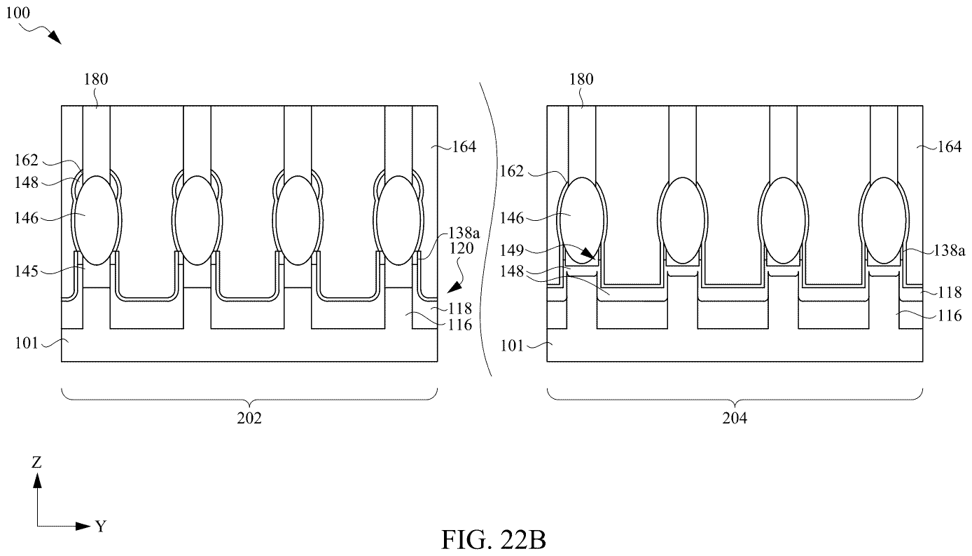

As shown in FIGS. 22A and 22B, conductive contacts 180 are formed in the ILD layer 164 to electrically connect with corresponding S/D regions 146 in the first and second regions 202, 204. The conductive contacts 180 may include one or more electrically conductive material, such as Ru, Mo, Co, Ni. W, Ti, Ta, Cu, Al, TiN and TaN. Silicide layers (not shown) may be disposed between the conductive contacts 180 and the S/D regions 146.

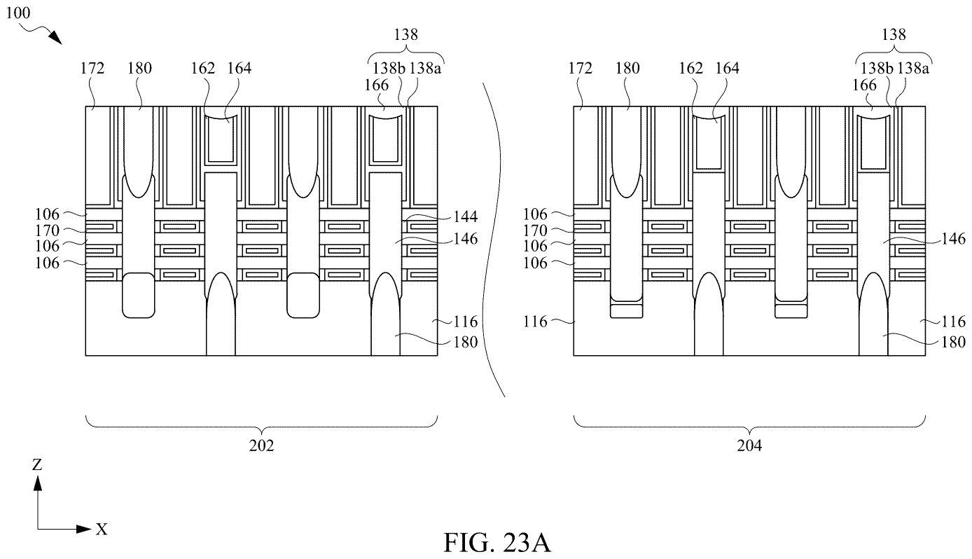

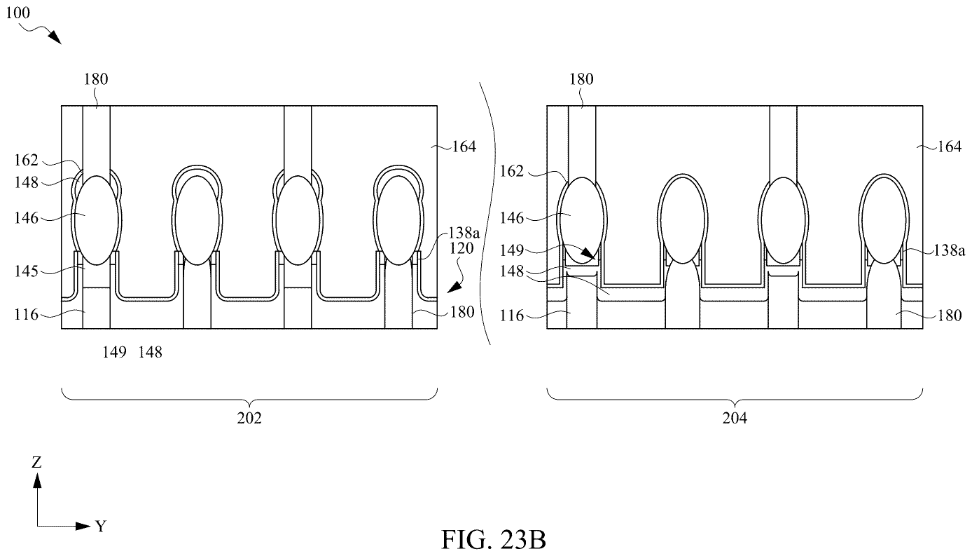

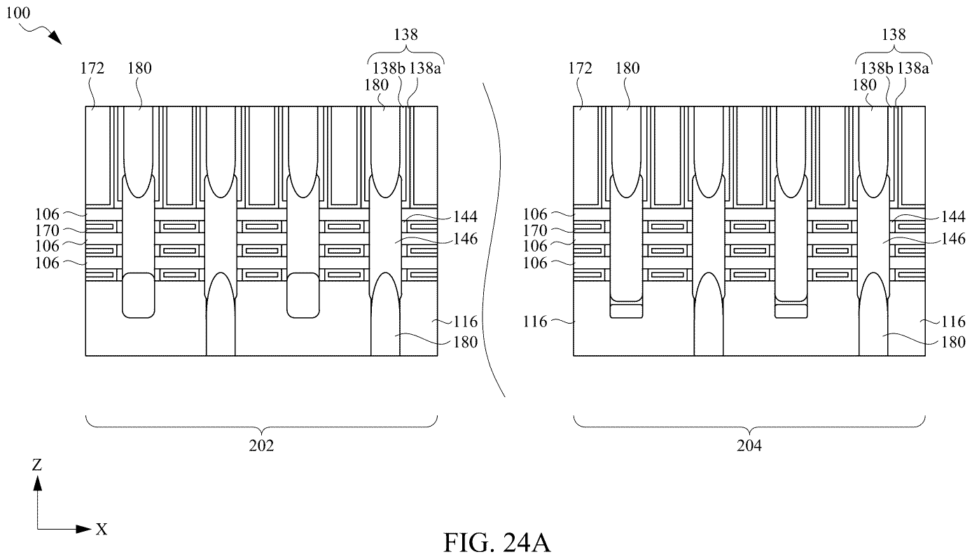

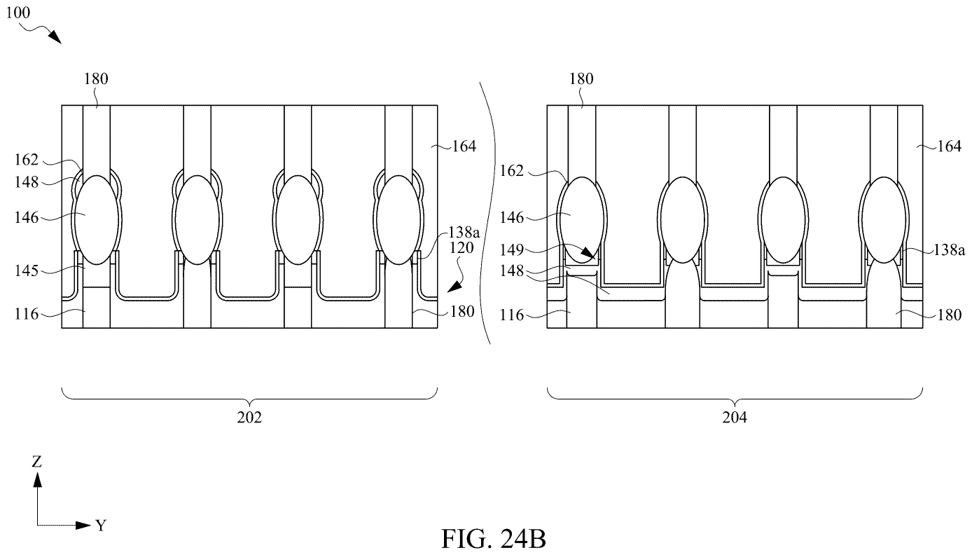

In some embodiments, the conductive contacts 180 are formed on a front side of the semiconductor device structure 100, as shown in FIGS. 22A and 22B. In some embodiments, some conductive contacts 180 are formed on a backside of the semiconductor device structure 100, as shown in FIGS. 23A and 23B. For example, the conductive contacts 180 electrically connected to the source regions of the S/D regions 146 are located on the backside of the semiconductor device structure 100, while the conductive contacts 180 electrically connected to the drain regions of the S/D regions 146 are located on the front side of the semiconductor device structure 100. In some embodiments, as shown in FIGS. 24A and 24B, the conductive contacts 180 for the source regions of the S/D regions 146 are located on both the front side and the backside of the semiconductor device structure 100, while the conductive contacts 180 for the drain regions of the S/D regions 146 are located on the front side of the semiconductor device structure 100.

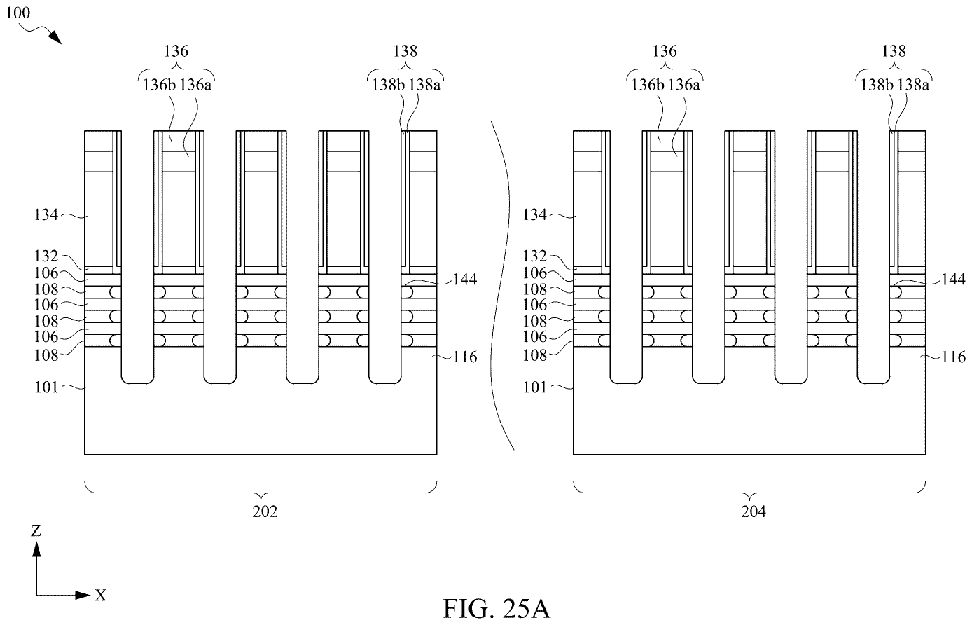

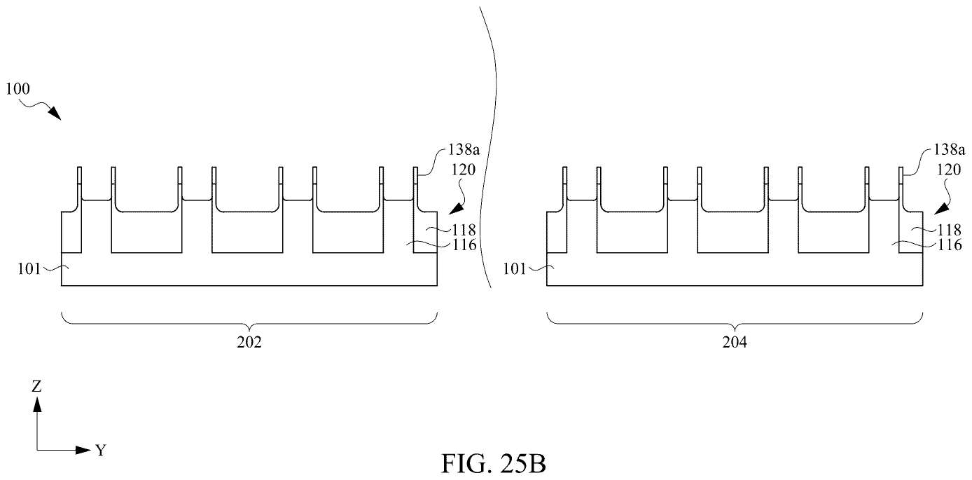

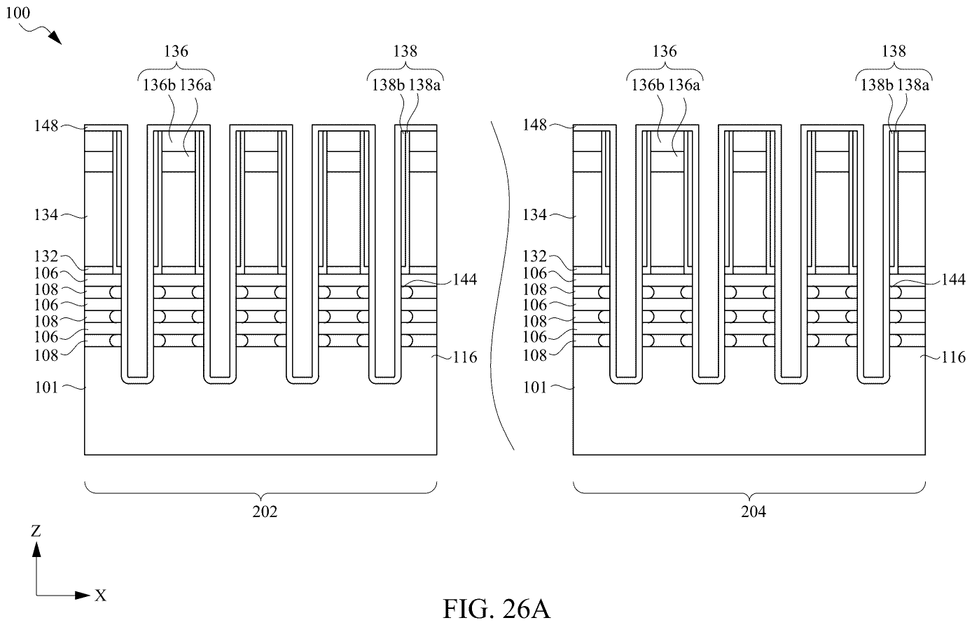

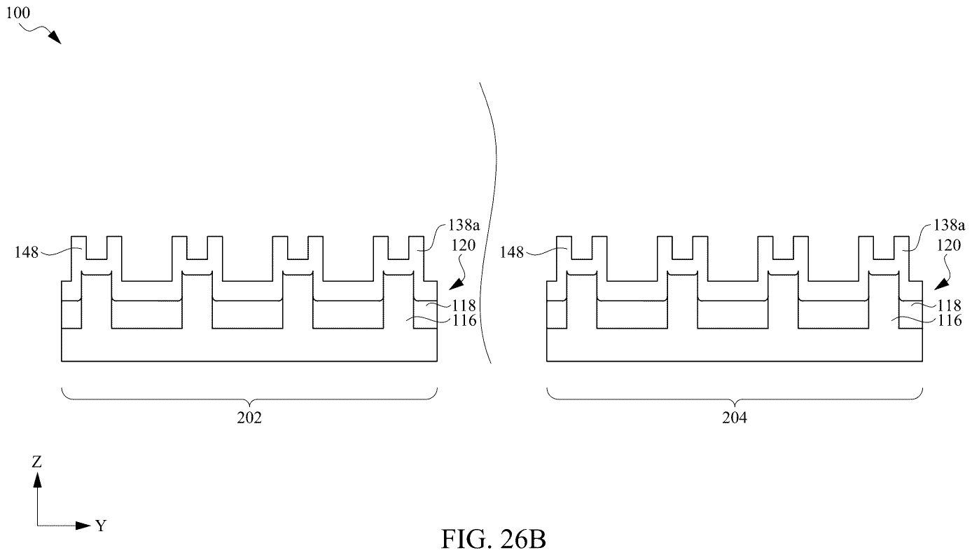

FIGS. 25A, 26A, 27A, 28A, 29A, 30A, 31A, 32A, 33A, 34A, 35A, 36A. 37A, 38A, 39A, 40A, and 41A are cross-sectional side views of various stages of manufacturing the semiconductor device structure 100 taken along line A-A of FIG. 5, in accordance with alternative embodiments. FIGS. 25B, 26B, 27B, 28B, 29B, 30B, 31B, 32B, 33B, 34B, 35B, 36B, 37B, 38B, 39B, 40B, and 41B are cross-sectional side views of various stages of manufacturing the semiconductor device structure 100 taken along line D-D of FIG. 5, in accordance with alternative embodiments. The semiconductor device structure 100 shown in FIGS. 25A and 25B are at the same manufacturing stage as the semiconductor device structure 100 shown in FIGS. 8A and 8B. Next, as shown in FIGS. 26A and 26B, the stressor layer 148 is deposited in the first and second regions 202, 204. As described above, the stressor layer 148 may be a single layer or a multi-layer structure. In some embodiments, the stressor layer 148 includes the first layer 148a and the second layer 148b (FIG. 13C).

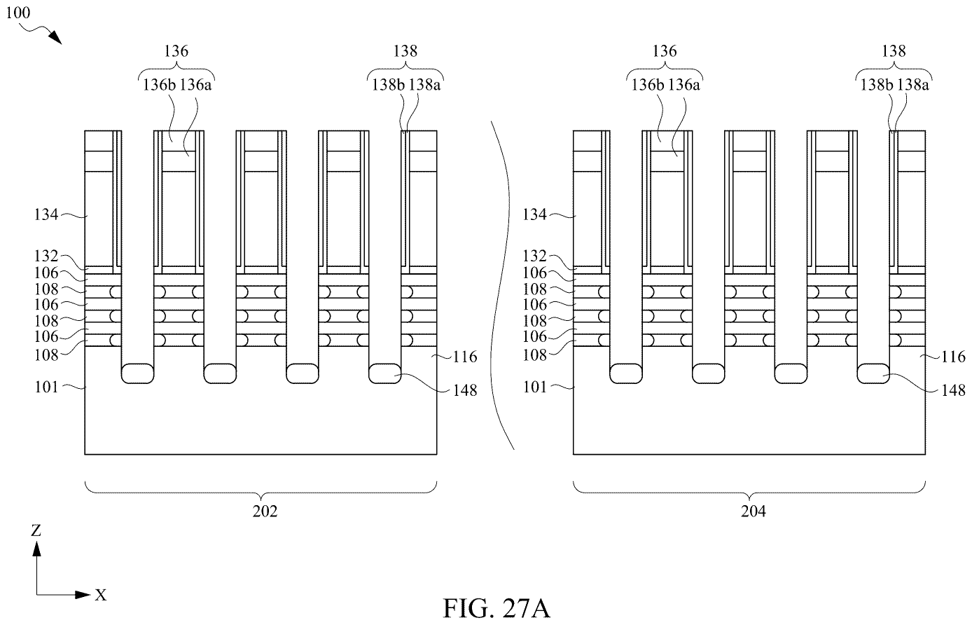

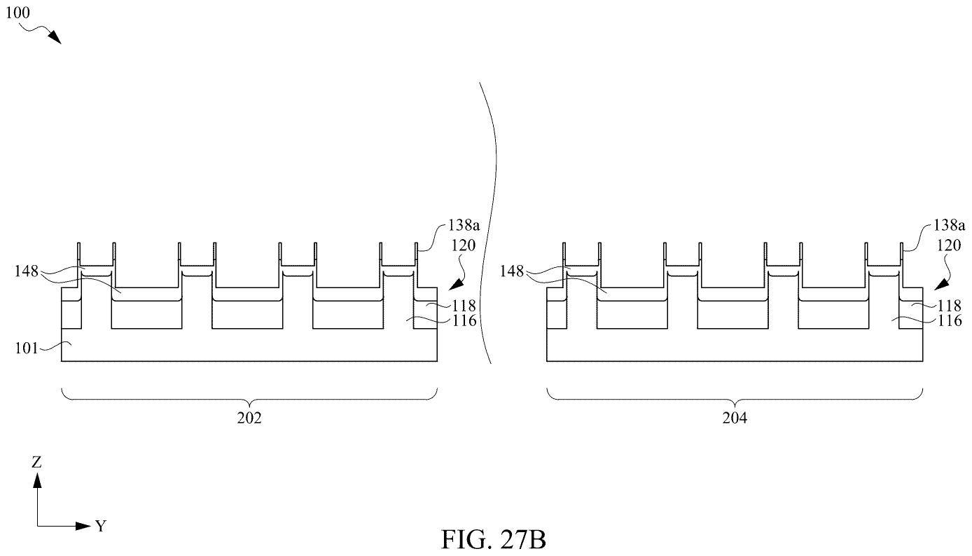

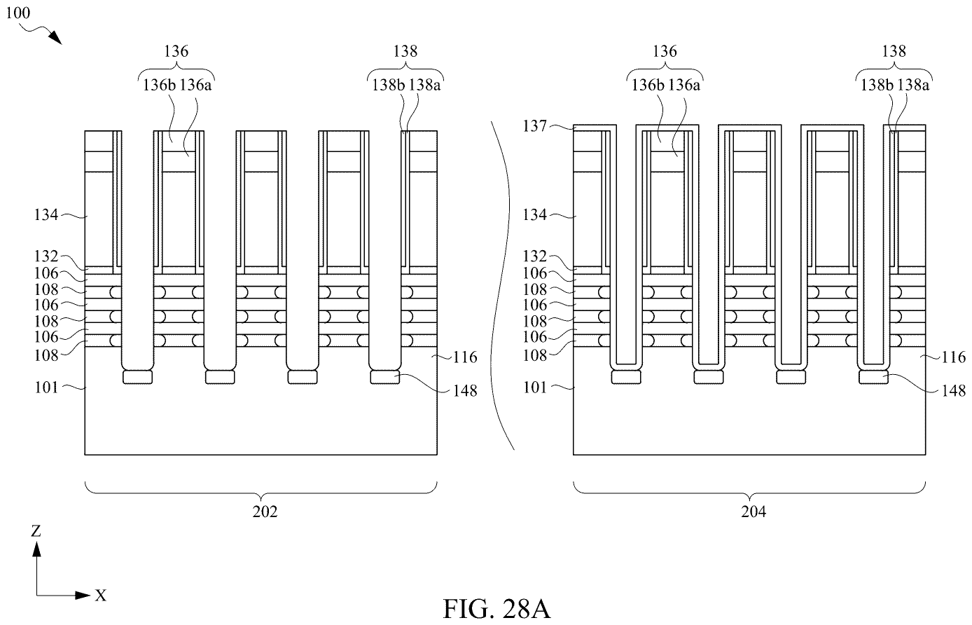

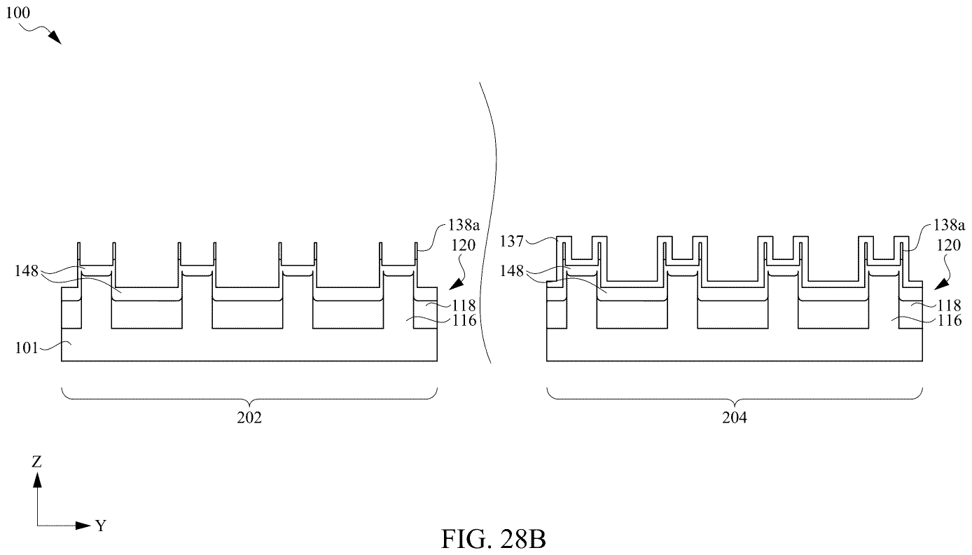

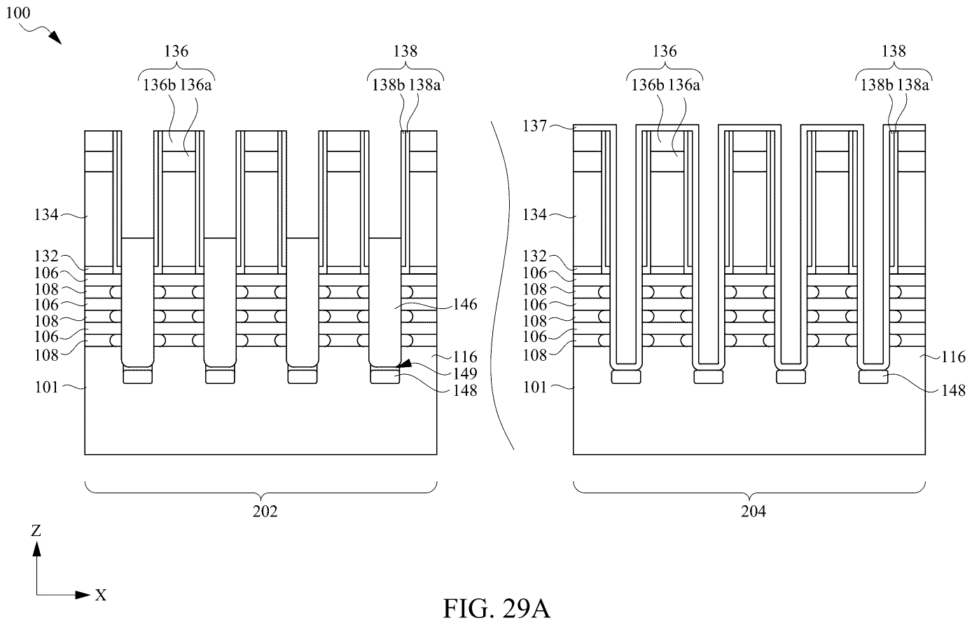

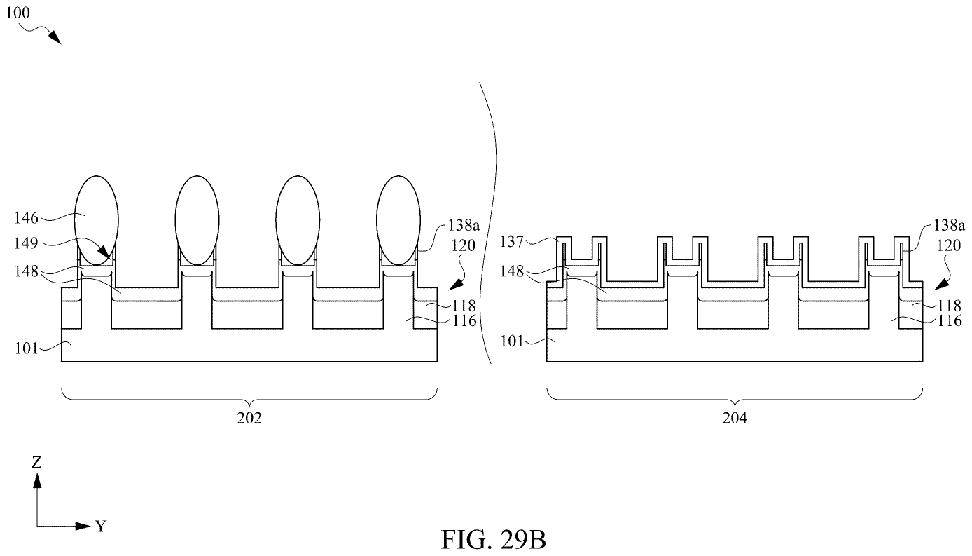

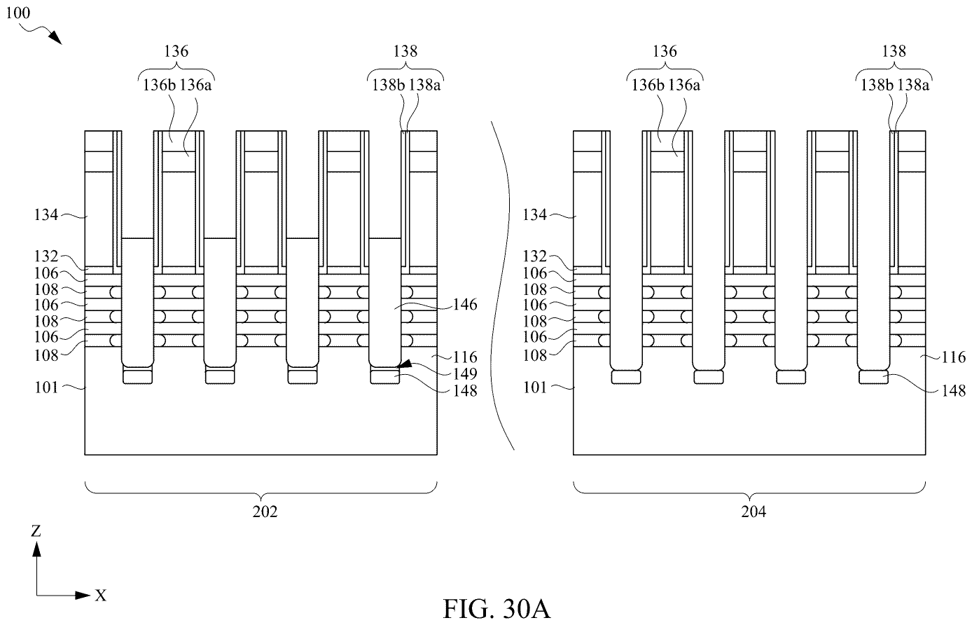

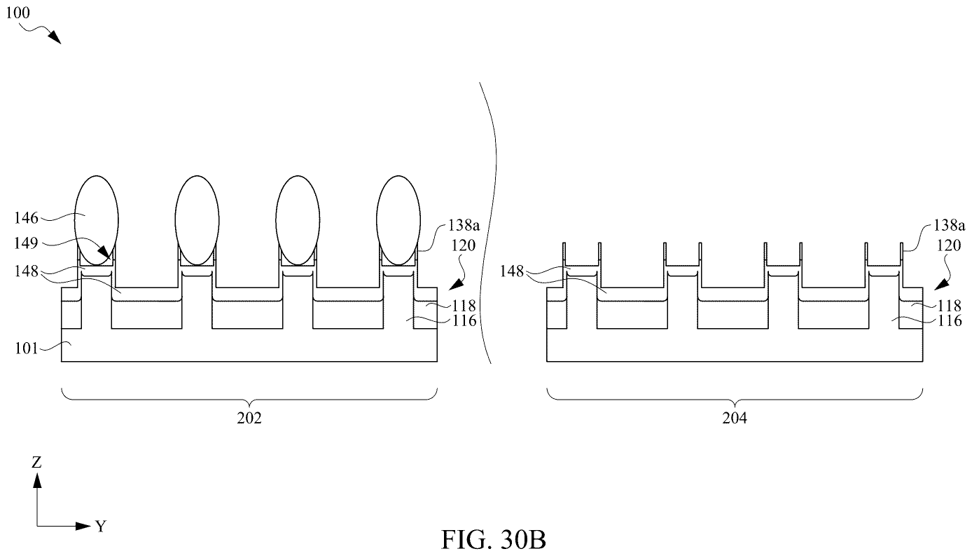

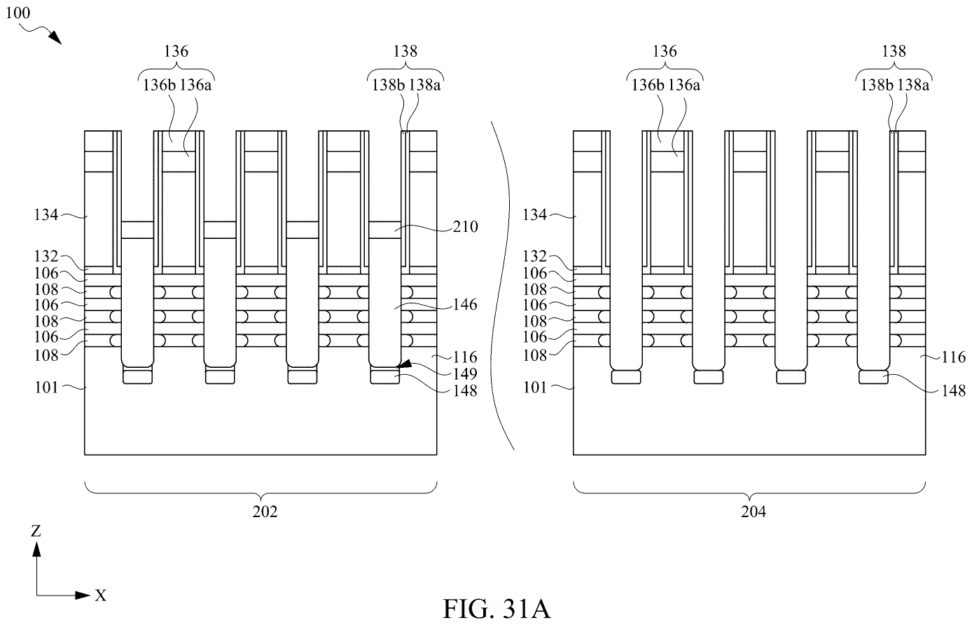

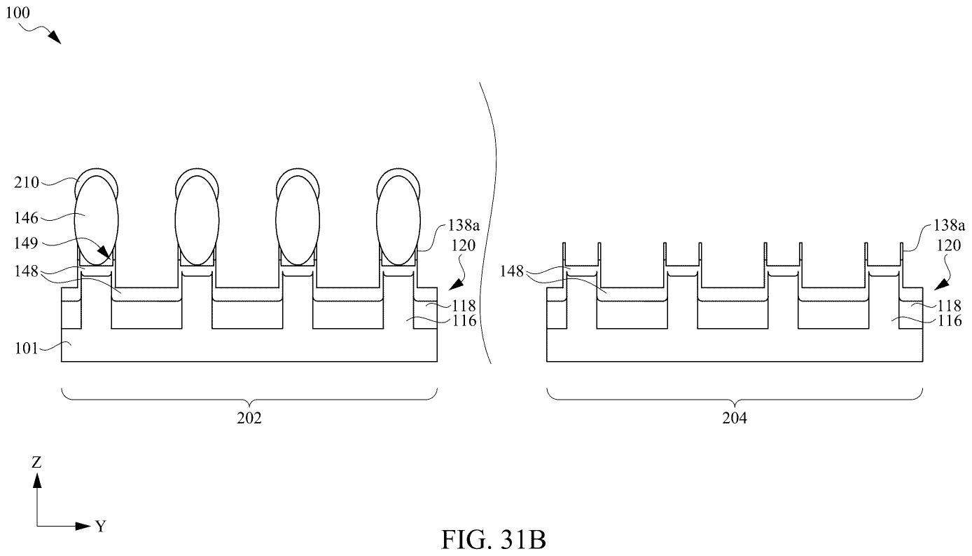

As shown in FIGS. 27A and 27B, a trimming process is performed on the stressor layer 148, and the remaining stressor layer 148 are disposed on the substrate portions 116 and the insulating material 118 in the first and second regions 202, 204. Next, the dielectric layer 137 is formed in the second region 204 to block the formation of the S/D regions 146 in the second region 204, as shown in FIGS. 28A and 28B. As shown in FIGS. 29A and 29B, the S/D regions 146 are formed in the first region 202, and the air gaps 149 are formed between the S/D regions 146 and the stressor layer 148. The air gaps 149 may be formed by the same processes described in FIGS. 15A and 15B. As shown in FIGS. 30A and 30B, the dielectric layer 137 is removed from the second region 204. Next, as shown in FIGS. 31A and 31B, another stressor layer 210 is formed on the S/D regions 146 in the first region 202. The stressor layer 210 may include the same material as the stressor layer 148 or a different material than the stressor layer 148. In some embodiments, the stressor layer 148 includes the first layer 148a and the second layer 148b, and the stressor layer 210 includes a single layer. The single layer of the stressor layer 210 may include Si₃N₄. In some embodiments, the S/D regions 146 in the first region 202 has increased longitudinal stress due to the inclusion of carbon or germanium, the stressor layer 210 located on the top surface of the S/D regions 146, and the air gaps 149 formed between the S/D regions 146 and the stressor layer 148. As a result, charge carrier mobility of the S/D regions 146 in the first region 202 is improved. The stressor layer 210 may be first deposited in the first and second regions 202, 204 and followed by a trimming process to remove the portions of the stressor layer 210 other than the portions of the stressor layer 210 formed on the top surface of the S/D regions 146 in the first region 202. Similar to the stressor layer 148, the stressor layer 210 has varying thicknesses. As described above, the trimming process performed on the stressor layer 210 having varying thicknesses can lead to the stressor layer 210 remaining on the top surface of the S/D regions 146 in the first region 202. In some embodiments, portions of the stressor layer 210 (not shown) may remain on the stressor layer 148 in the second region 204. In some embodiments, the stressor layer 210 is selectively deposited on the semiconductor material of the S/D regions 146 and not on the dielectric materials of the other components of the semiconductor device structure 100.

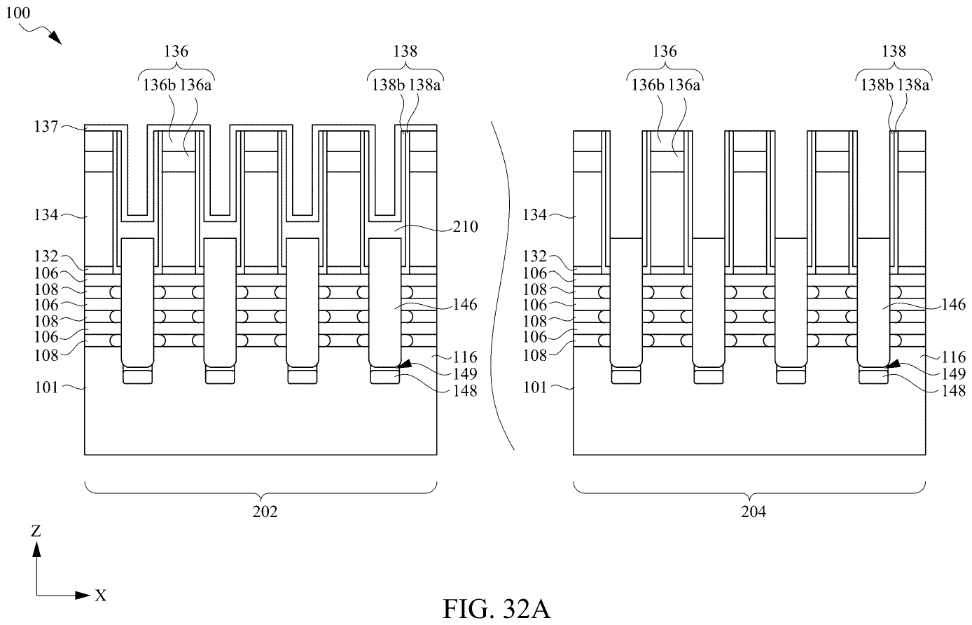

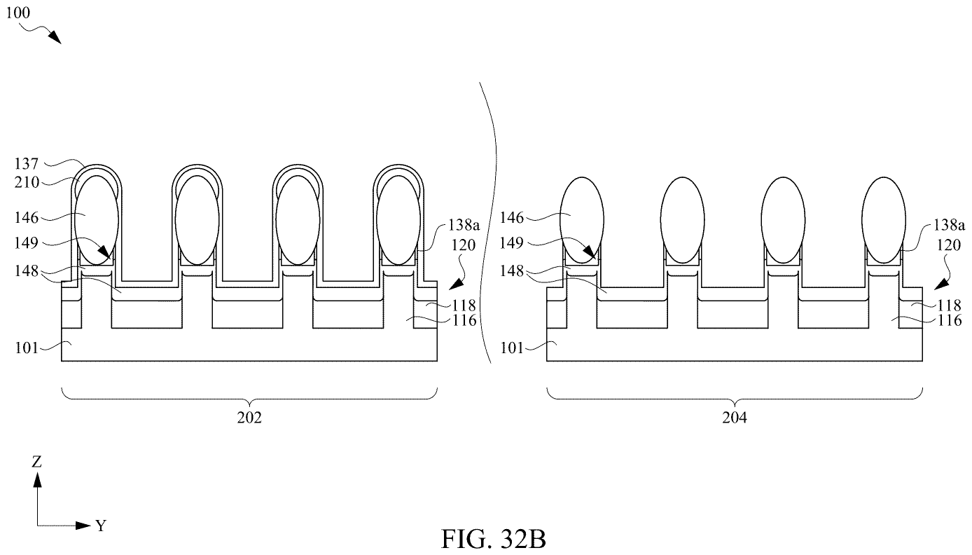

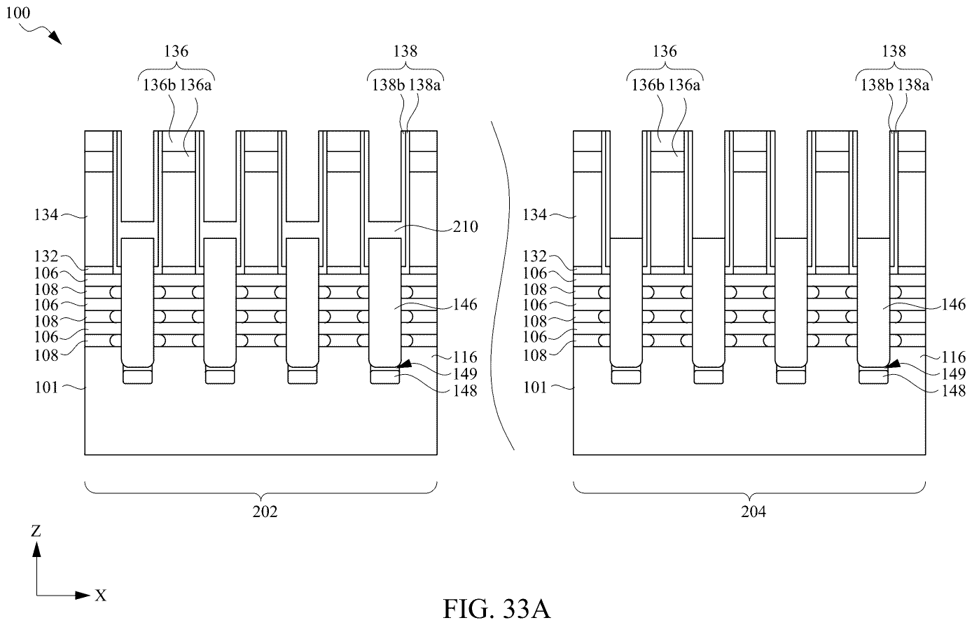

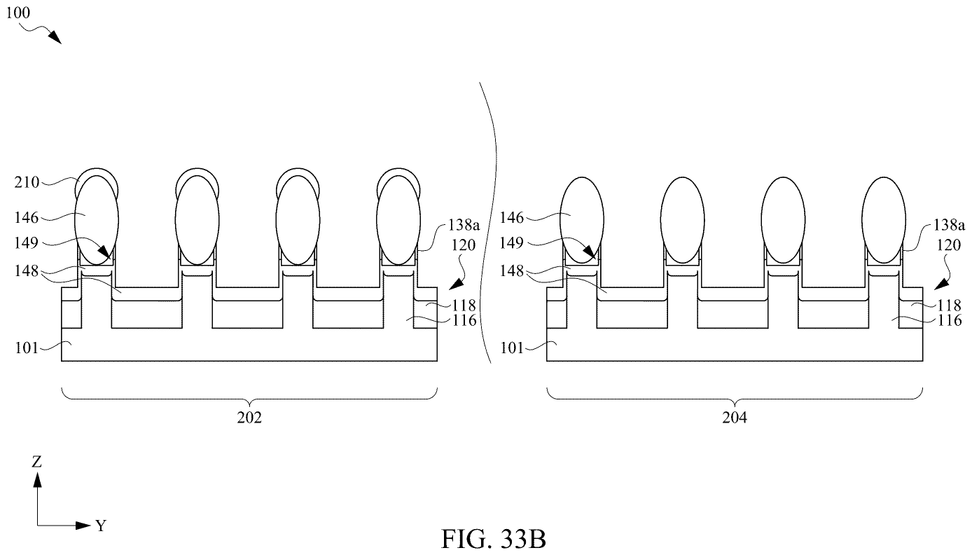

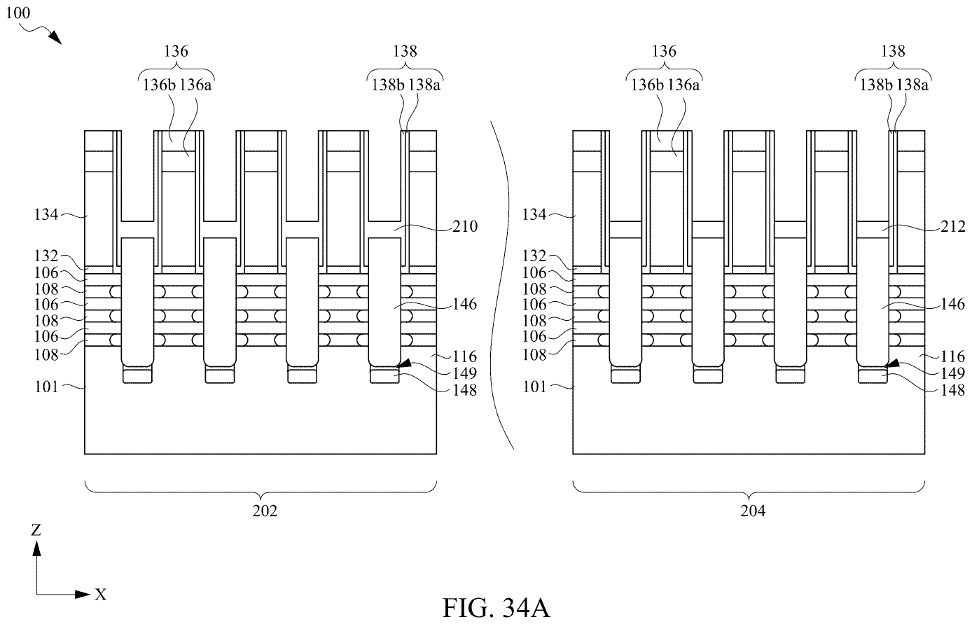

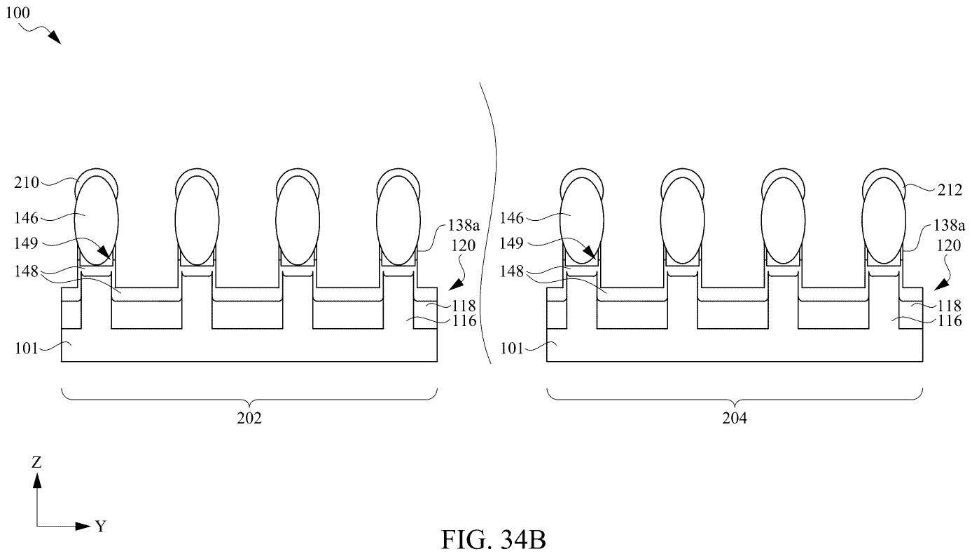

As shown in FIGS. 32A and 32B, another dielectric layer 137 is formed in the first region 202, and the S/D regions 146 are formed in the second region 204. Next, as shown in FIGS. 33A and 33B, the dielectric layer 137 is removed from the first region 202. Another stressor layer 212 is formed on the top surface of the S/D regions 146 in the second region 204, as shown in FIGS. 34A and 34B. The stressor layer 212 may include the same material as the stressor layer 210 or a different material than the stressor layer 210. In some embodiments, the stressor layer 212 is selectively deposited on the semiconductor material of the S/D regions 146 and not on the dielectric materials of the other components of the semiconductor device structure 100. In some embodiments, the S/D regions 146 in the second region 204 has increased longitudinal stress due to the inclusion of carbon or germanium, the stressor layer 212 located on the top surface of the S/D regions 146, and the air gaps 149 formed between the S/D regions 146 and the stressor layer 148. As a result, charge carrier mobility of the S/D regions 146 in the second region 204 is improved.

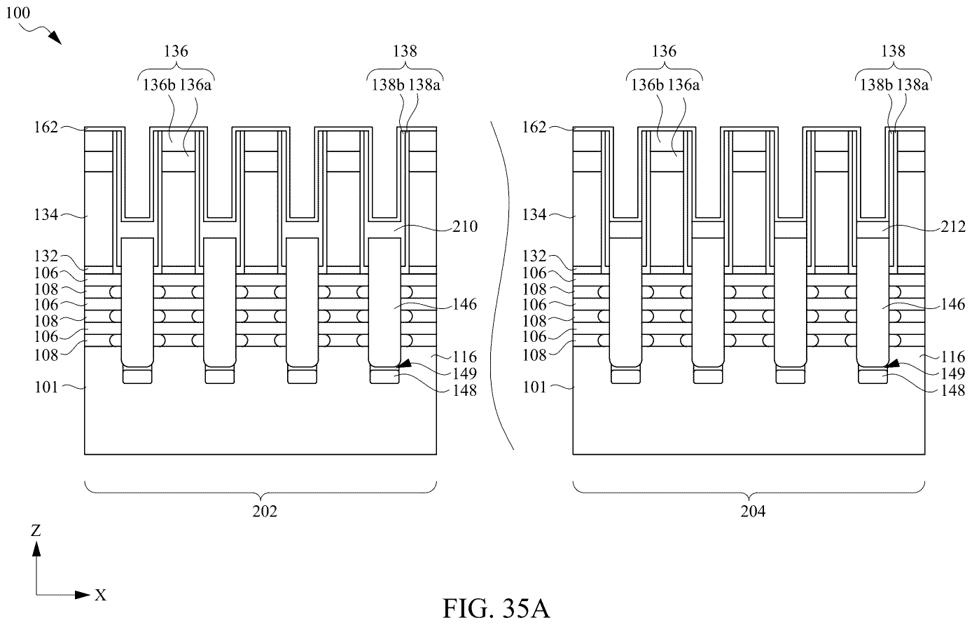

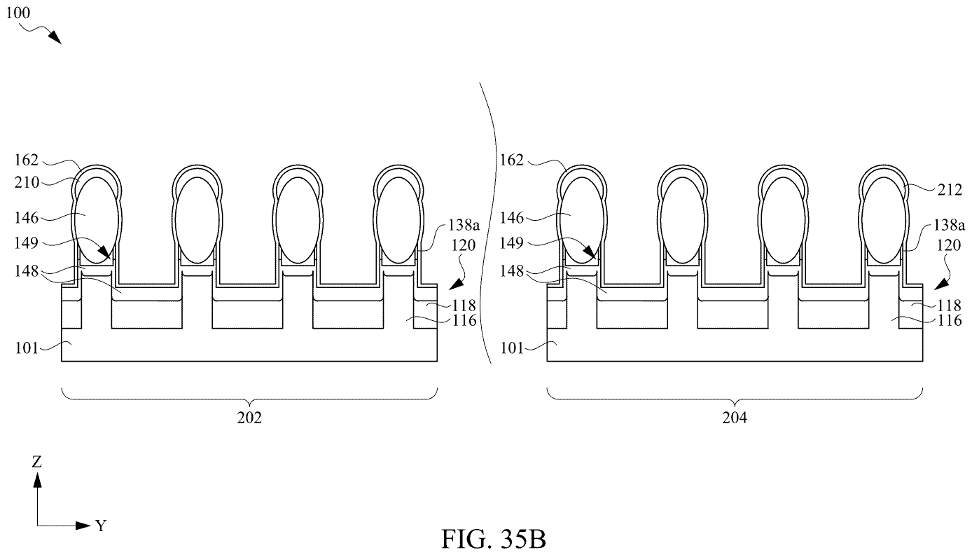

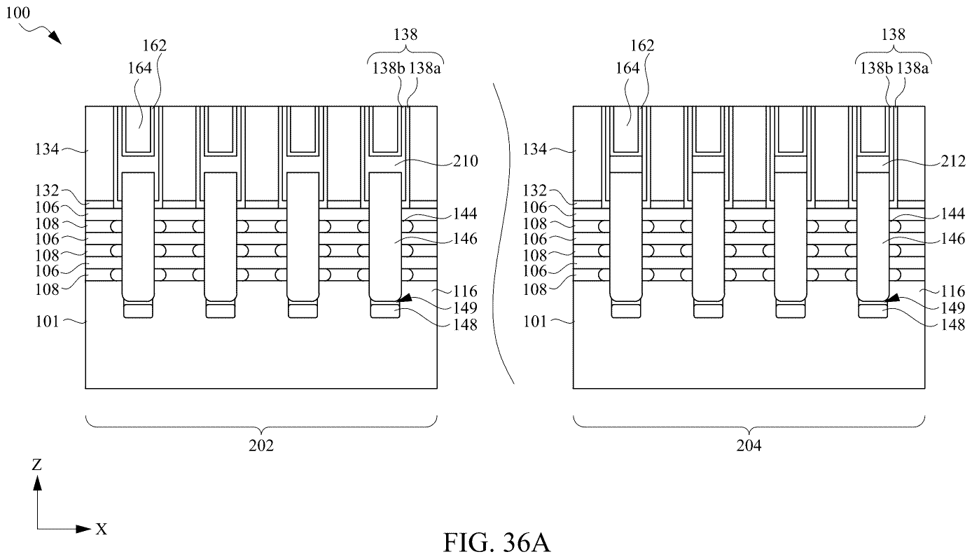

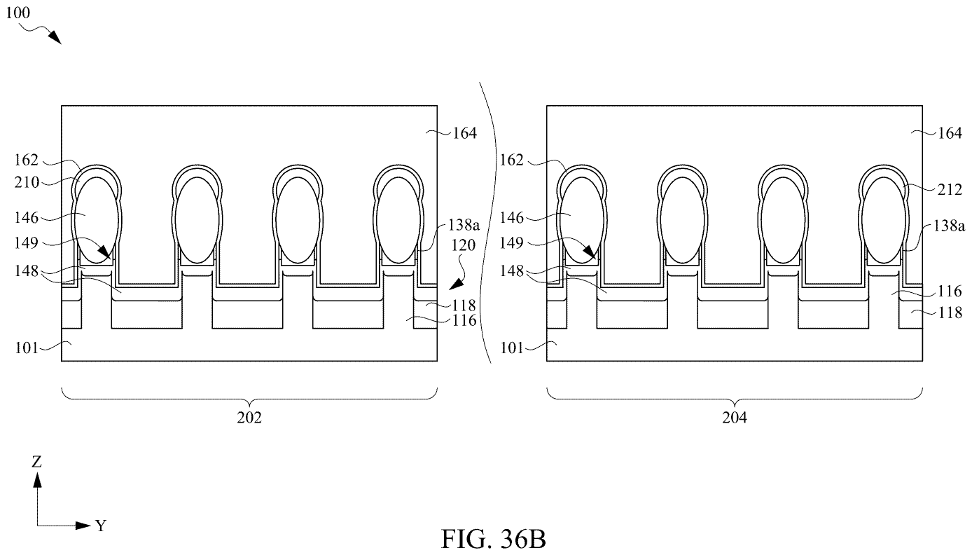

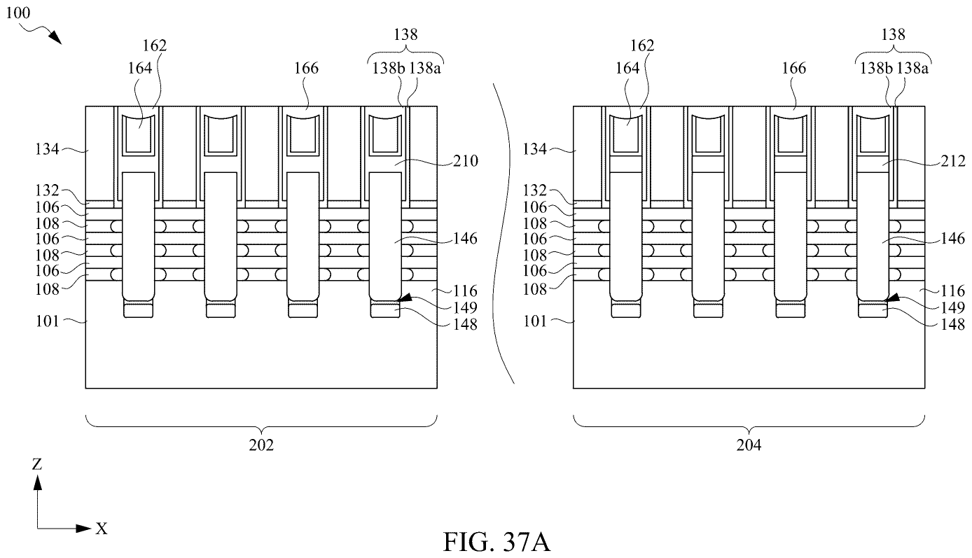

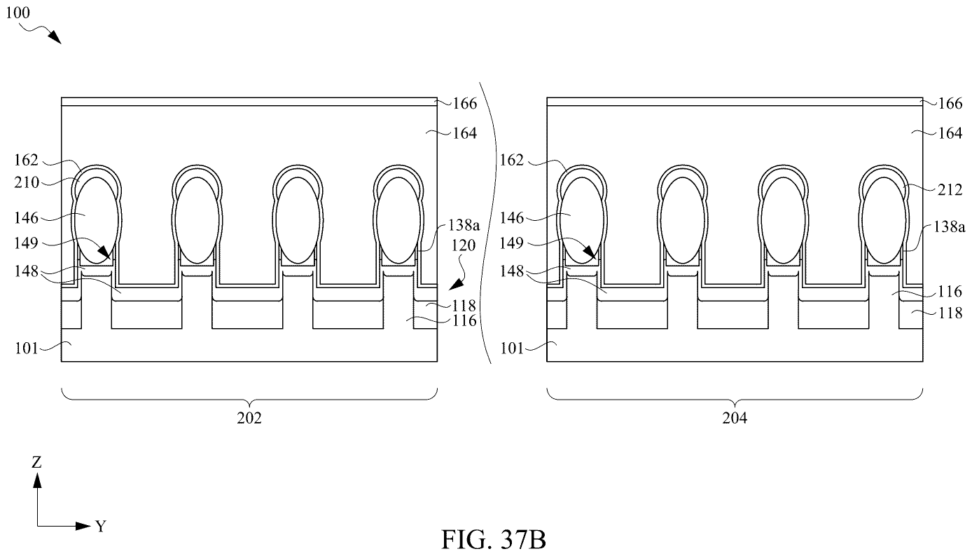

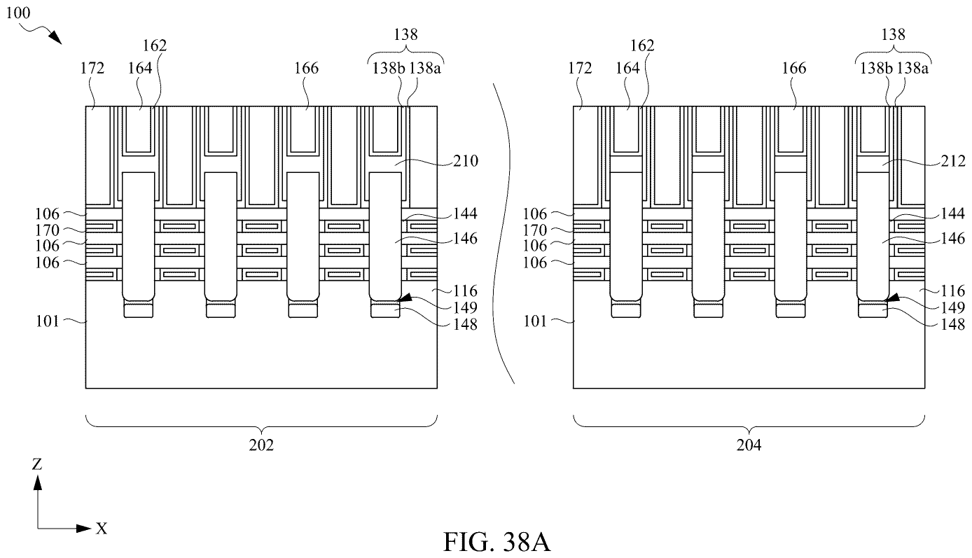

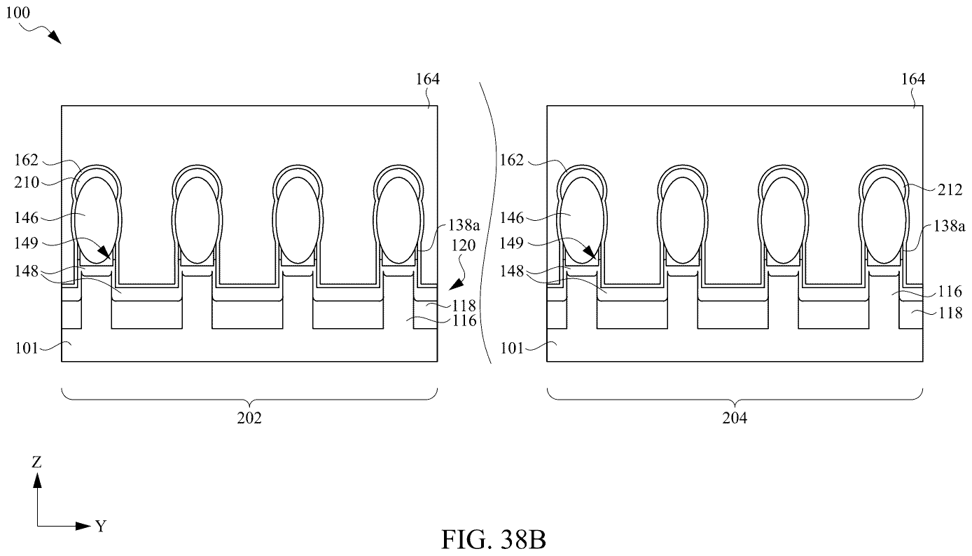

As shown in FIGS. 35A and 35B, the CESL 162 is deposited in the first and second regions 202, 204. Next, the ILD layer 164 is deposited on the CESL 162 in the first and second regions 202, 204, as shown in FIGS. 36A and 36B. The dielectric layer 166 may be formed on the recessed ILD layer 164, as shown in FIGS. 37A and 37B. Next, the sacrificial gate stack 130 and the second semiconductor layers 108 are removed and replaced with the gate dielectric layer 170 and the gate electrode layer 172, as shown in FIGS. 38A and 38B. After the deposition of the gate electrode layer 172, a CMP process may be performed to remove the portions of the gate dielectric layer 170 and gate electrode layer 172 formed over the ILD layer 164, and the dielectric layer 166 may be also removed by the CMP process.

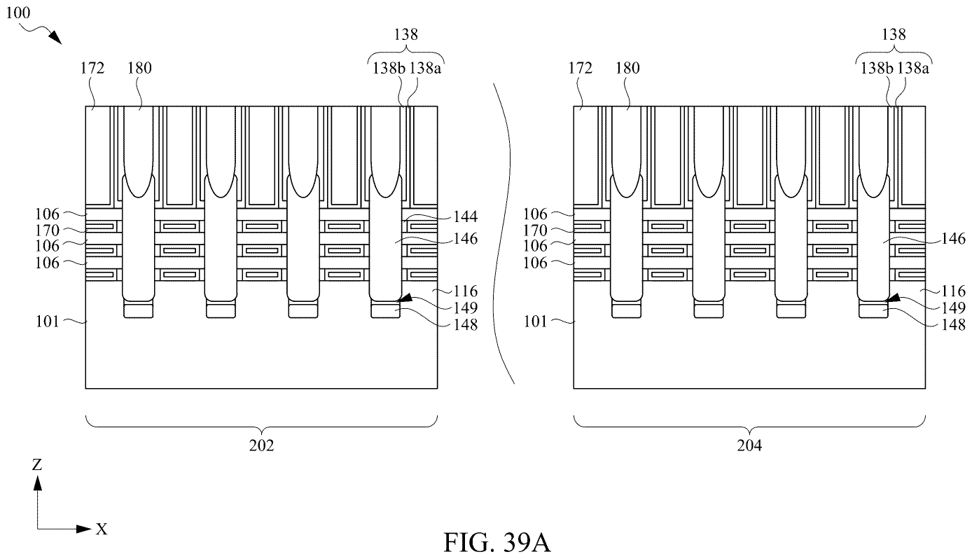

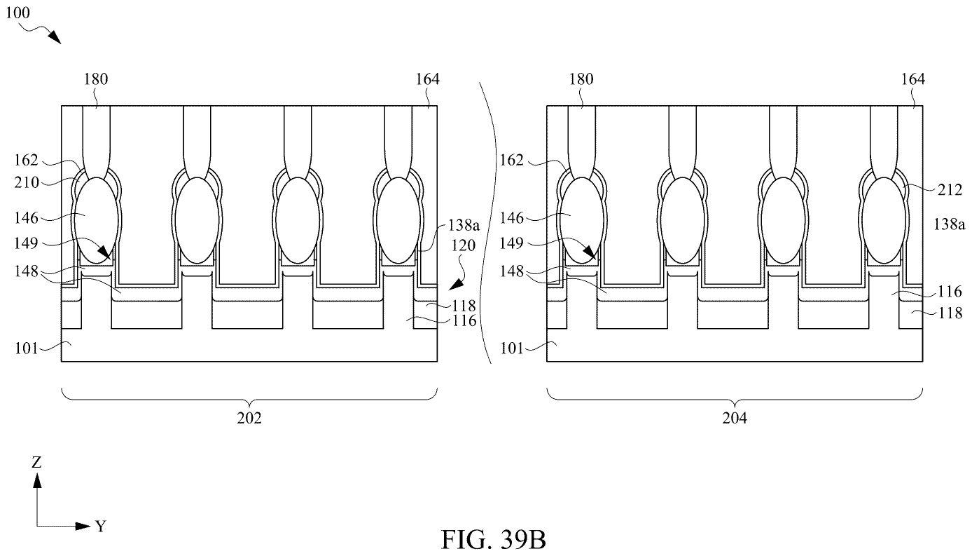

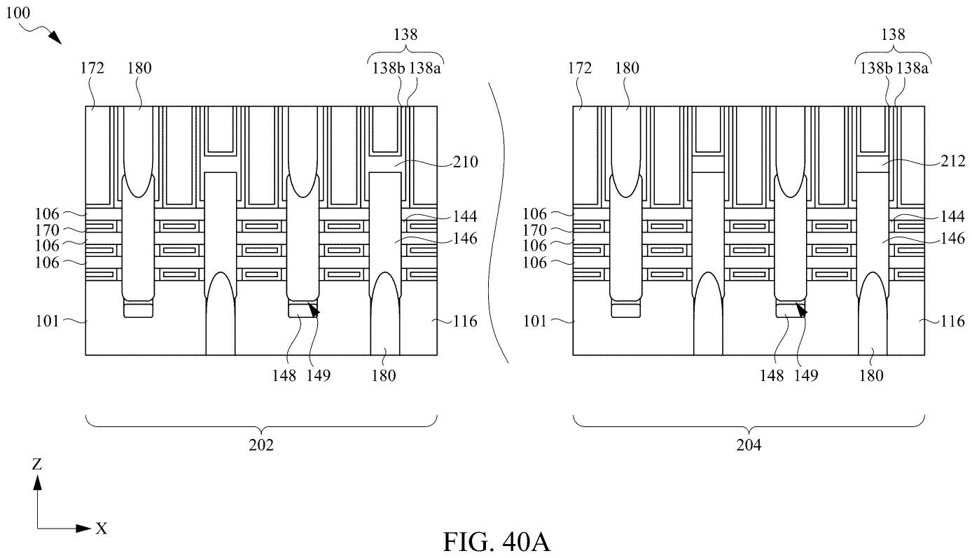

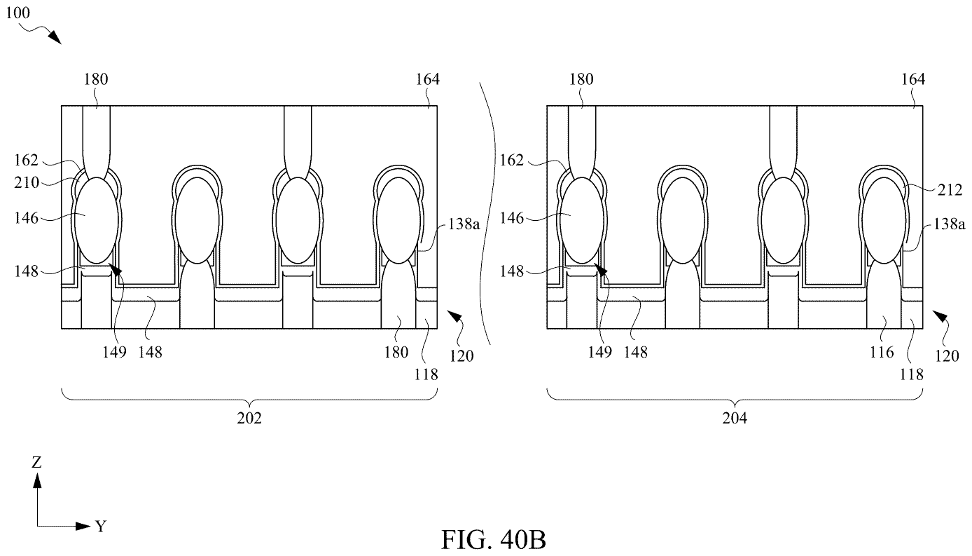

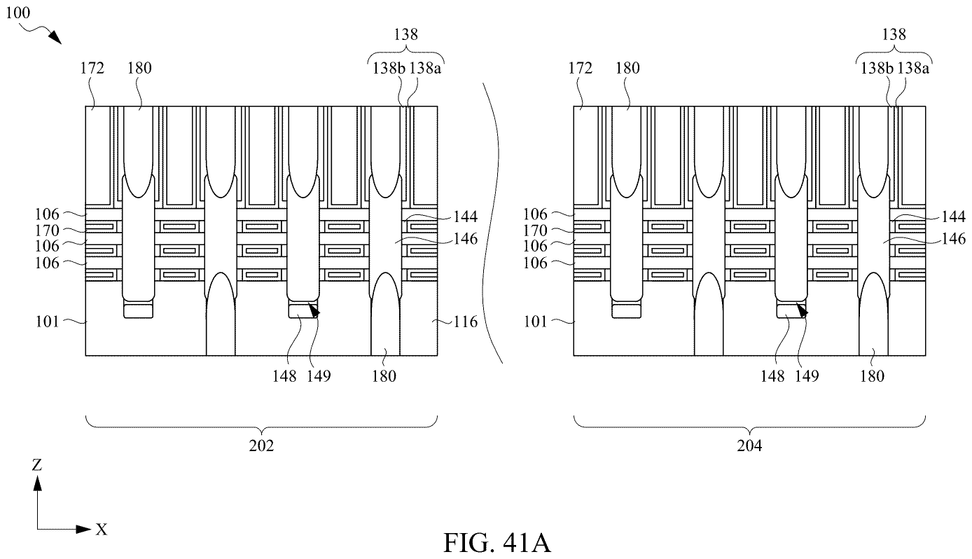

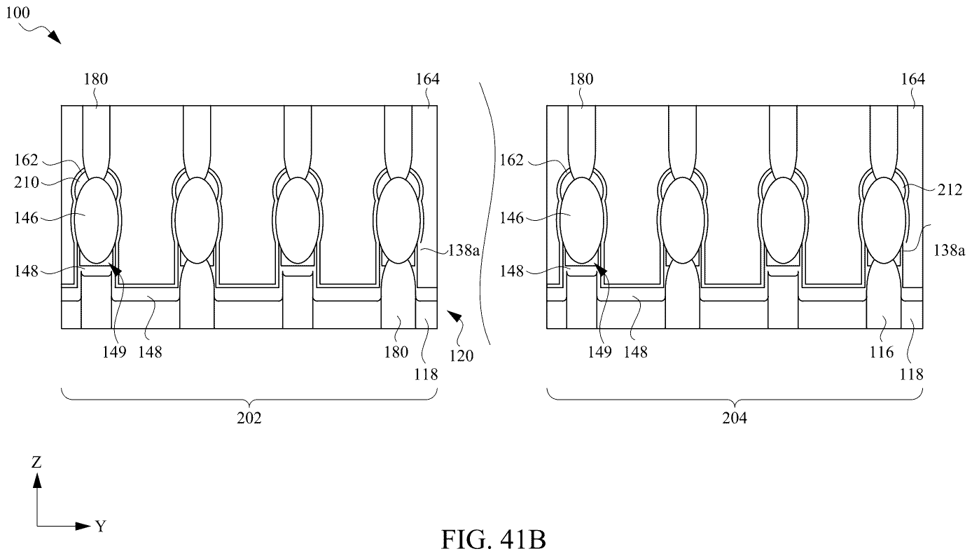

As shown in FIGS. 39A and 39B, the conductive contacts 180 are formed on the front side of the semiconductor device structure 100. The conductive contacts 180 for the source regions of the S/D regions 146 may be formed on the backside of the semiconductor device structure 100, as shown in FIGS. 40A and 40B. In some embodiments, as shown in FIGS. 41A and 41B, the conductive contacts 180 for the source regions of the S/D regions 146 are located on both the front side and the backside of the semiconductor device structure 100, while the conductive contacts 180 for the drain regions of the S/D regions 146 are located on the front side of the semiconductor device structure 100.

Embodiments of the present disclosure provide a semiconductor device structure and methods of forming the same. In some embodiments, the semiconductor device structure includes an air gap 149 formed between the S/D region 146 and a stressor layer 148. Furthermore, the S/D region 146 may include carbon or germanium, and another stressor layer 210 (or 212) may be formed on the S/D region 146. Some embodiments may achieve advantages. For example, the longitudinal stress of the S/D region 146 is increased due to the inclusion of carbon or germanium, the stressor layer 210 (or 212) located on the top surface of the S/D region 146, and the air gap 149 formed between the S/D region 146 and the stressor layer 148. As a result, charge carrier mobility of the S/D region 146 is improved.

An embodiment is a semiconductor device structure. The structure includes one or more semiconductor layers disposed over a substrate portion, a source/drain region disposed adjacent the substrate portion and the one or more semiconductor layers, and a first stressor layer disposed below the source/drain region, wherein an air gap is formed between the first stressor layer and the source/drain region.

Another embodiment is a semiconductor device structure. The structure includes a first source/drain region disposed adjacent a first substrate portion in a first region and a first stressor layer disposed below the first source/drain region in the first region. An air gap is formed between the first stressor layer and the first source/drain region. The structure further includes a second source/drain region disposed adjacent a second substrate portion in a second region and a second stressor layer disposed on a top surface of the second source/drain region in the second region.

A further embodiment is a method for forming a semiconductor device structure. The method includes forming a first fin structure in a first region and a second fin structure in a second region and recessing the first and second fin structures. A first substrate portion is exposed in the first region and a second substrate portion is exposed in the second region. The method further includes forming a first source/drain region in the first region, forming a stressor layer on a top surface of the first source/drain region in the first region and on the second substrate portion in the second region, and forming a second source/drain region over the stressor layer in the second region. An air gap is formed between the second source/drain region and the stressor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
one or more semiconductor layers disposed over a substrate portion;
a source/drain region disposed adjacent the substrate portion and the one or more semiconductor layers; and
a first stressor layer disposed below the source/drain region, wherein an air gap is formed between the first stressor layer and the source/drain region.

2. The semiconductor device structure of claim 1, further comprising a second stressor layer disposed on a top surface of the source/drain region.

3. The semiconductor device structure of claim 2, further comprising a contact etch stop layer disposed on the second stressor layer.

4. The semiconductor device structure of claim 1, wherein the first stressor layer comprises a first layer and a second layer disposed on the first layer.

5. The semiconductor device structure of claim 4, wherein the first layer comprises Si₃N₄ and the second layer comprises SiO₂.

6. The semiconductor device structure of claim 5, wherein the source/drain region includes an element, and a concentration of the element decreases from a bottom of the source/drain region.

7. The semiconductor device structure of claim 6, wherein the element is carbon or germanium.

8. A semiconductor device structure, comprising:
a first source/drain region disposed adjacent a first substrate portion in a first region;
a first stressor layer disposed below the first source/drain region in the first region, wherein an air gap is formed between the first stressor layer and the first source/drain region
a second source/drain region disposed adjacent a second substrate portion in a second region; and
a second stressor layer disposed on a top surface of the second source/drain region in the second region.

9. The semiconductor device structure of claim 8, further comprising a semiconductor material disposed adjacent the second substrate portion in the second region, wherein the second source/drain region is disposed on and in contact with the semiconductor material.

10. The semiconductor device structure of claim 8, wherein the first stressor layer comprises a first layer and a second layer disposed on the first layer, and the second stressor layer comprises the first layer and the second layer disposed on the first layer.

11. The semiconductor device structure of claim 10, wherein the first layer comprises Si₃N₄ and the second layer comprises SiO₂.

12. The semiconductor device structure of claim 8, wherein the first stressor layer comprises a first layer and a second layer disposed on the first layer, and the second stressor layer comprises a single layer.

13. The semiconductor device structure of claim 8, wherein the first region is an NMOS region.

14. The semiconductor device structure of claim 13, wherein the first source/drain region comprises carbon, and a concentration of the carbon decreases from a bottom of the first source/drain region.

15. The semiconductor device structure of claim 8, wherein the first region is a PMOS region.

16. The semiconductor device structure of claim 15, wherein the first source/drain region comprises germanium, and a concentration of the germanium decreases from a bottom of the first source/drain region.

17. A method for forming a semiconductor device structure, comprising:
forming a first fin structure in a first region and a second fin structure in a second region;
recessing the first and second fin structures, wherein a first substrate portion is exposed in the first region and a second substrate portion is exposed in the second region;
forming a first source/drain region in the first region;
forming a stressor layer on a top surface of the first source/drain region in the first region and on the second substrate portion in the second region; and
forming a second source/drain region over the stressor layer in the second region, wherein an air gap is formed between the second source/drain region and the stressor layer.

18. The method of claim 17, wherein the stressor layer comprises a first layer and a second layer disposed on the first layer.

19. The method of claim 18, wherein the first layer comprises Si₃N₄ and the second layer comprises SiO₂.

20. The method of claim 19, wherein a precursor of the second source/drain region reacts with the second layer to form a gas or a water-soluble material.
